(19) United States
(12) Patent Application Publication
(10) Pub. No.: US 2026/0162692 A1
(43) Pub. Date: Jun. 11, 2026

(54) SEMICONDUCTOR MEMORY DEVICE

(71) Applicant: Kioxia Corporation, Tokyo (JP)

(72) Inventor: Takuya NISHIKAWA, Yokkaichi Mie (JP)

(73) Assignee: Kioxia Corporation, Tokyo (JP)

(21) Appl. No.: 19/227,572

(22) Filed: Jun. 4, 2025

(30) Foreign Application Priority Data
Dec. 6, 2024 (JP) 2024-213130

(51) Int. Cl. G11C 5/06; H01L 23/00; H10B 43/10; H10B 43/27

(52) U.S. Cl. CPC G11C 5/063; H10B 43/10; H10B 43/27; H10W 90/792

(57) ABSTRACT

A semiconductor memory device of an embodiment includes: a first stacked body in which a plurality of conductive layers is stacked apart from each other; a second stacked body that is disposed at a predetermined depth in the first stacked body in a stacking direction of the first stacked body, in which a plurality of first insulating layers is stacked apart from each other at height positions corresponding to conductive layers located within the predetermined depth among the plurality of conductive layers; and a plurality of columnar portions that extends in the first and second stacked bodies in the stacking direction, wherein the second stacked body is disposed in an island shape in the first stacked body at a position corresponding to one or more columnar portions among the plurality of columnar portions when viewed in the stacking direction.

### CROSS-REFERENCE TO RELATED APPLICATIONS

This application is based upon and claims the benefit of priority from Japanese Patent Application No. 2024-213130, filed on Dec. 6, 2024; the entire contents of which are incorporated herein by reference.

### FIELD

Embodiments described herein relate generally to a semiconductor memory device.

### BACKGROUND

When a semiconductor memory device such as a three-dimensional nonvolatile memory is manufactured, a process of alternately stacking a plurality of sacrificial layers and a plurality of insulating layers one by one, and forming a plurality of conductive layers in gaps between the insulating layers after removing the sacrificial layers may be included. However, after the removal of the sacrificial layers, the remaining insulating layers may be bent or the entire structure may be distorted.

### BRIEF DESCRIPTION OF THE DRAWINGS

FIGS. 1A and 1B are views illustrating a schematic configuration example of a semiconductor memory device according to an embodiment;

FIGS. 2A to 2E are views illustrating an example of a configuration of the semiconductor memory device according to the embodiment;

FIGS. 3A and 3B are views illustrating an example of the configuration of the semiconductor memory device according to the embodiment;

FIGS. 4A to 4E are cross-sectional views sequentially illustrating a part of a procedure of a method for manufacturing the semiconductor memory device according to the embodiment;

FIGS. 5A to 5D are cross-sectional views sequentially illustrating a part of a procedure of the method for manufacturing the semiconductor memory device according to the embodiment;

FIGS. 6A to 6D are cross-sectional views sequentially illustrating a part of a procedure of the method for manufacturing the semiconductor memory device according to the embodiment;

FIGS. 7A to 7C are cross-sectional views sequentially illustrating a part of a procedure of the method for manufacturing the semiconductor memory device according to the embodiment;

FIGS. 8A to 8C are cross-sectional views sequentially illustrating a part of a procedure of the method for manufacturing the semiconductor memory device according to the embodiment;

FIGS. 9A to 9D are cross-sectional views sequentially illustrating a part of a procedure of the method for manufacturing the semiconductor memory device according to the embodiment;

FIGS. 10A to 10C are cross-sectional views sequentially illustrating a part of a procedure of the method for manufacturing the semiconductor memory device according to the embodiment;

FIGS. 11A to 11C are cross-sectional views sequentially illustrating a part of a procedure of the method for manufacturing the semiconductor memory device according to the embodiment;

FIGS. 12A to 12E are XY cross-sectional views at a height position of a select gate line illustrating some examples of a configuration of a block layer included in a semiconductor memory device according to a first modification of the embodiment;

FIGS. 13A to 13C are cross-sectional views illustrating an example of a configuration of a semiconductor memory device according to a second modification of the embodiment; and

FIG. 14 is a cross-sectional view illustrating a schematic configuration example of a semiconductor memory device according to another modification of the embodiment.

### DETAILED DESCRIPTION

A semiconductor memory device of an embodiment includes: a first stacked body in which a plurality of conductive layers is stacked apart from each other; a second stacked body that is disposed at a predetermined depth in the first stacked body in a stacking direction of the first stacked body, in which a plurality of first insulating layers is stacked apart from each other at height positions corresponding to conductive layers located within the predetermined depth among the plurality of conductive layers; a plurality of pillars that is disposed in a first region and extends in the first stacked body in the stacking direction, in which a memory cell is formed at each of intersection portions with at least a part of the plurality of conductive layers; and a plurality of columnar portions that is disposed in a second region different from the first region and extends in the first and second stacked bodies in the stacking direction, wherein the second stacked body is disposed in an island shape in the first stacked body at a position corresponding to one or more columnar portions among the plurality of columnar portions when viewed in the stacking direction.

Hereinafter, embodiments of the present invention will be described in detail with reference to the drawings. Note that the present invention is not limited by the embodiments described below. In addition, constituent elements in the embodiments described below include those that can be easily assumed by those skilled in the art or those that are substantially the same.

### Configuration Example of Semiconductor Memory Device

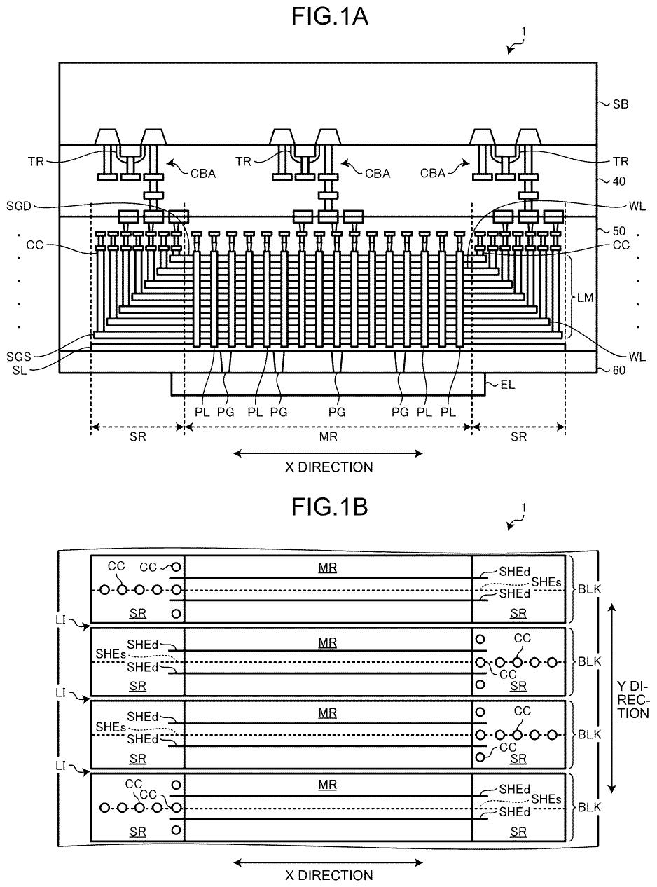

FIGS. 1A and 1B are views illustrating a schematic configuration example of a semiconductor memory device 1 according to an embodiment. More specifically, FIG. 1A is a cross-sectional view of the semiconductor memory device 1 along an X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and a part of upper layer wiring and the like is omitted.

In addition, in the present specification, both the X direction and the Y direction are directions along the orientation of surfaces of word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes an electrode film EL, a source line SL, one or more select gate lines SGS, a plurality of word lines WL, one or more select gate lines SGD, and a semiconductor substrate SB on which peripheral circuits CBA are provided in order from the lower side of the drawing.

The source line SL is disposed on the electrode film EL via an insulating layer 60. A plurality of plugs PG is disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. The select gate lines SGS, the plurality of word lines WL, and the select gate lines SGD are stacked in this order above the source line SL to form a stacked body LM.

Note that, in the present specification, in the stacked body LM, the side on which the select gate lines SGD are disposed is defined as an upward direction in the semiconductor memory device 1, and the side on which the select gate lines SGS are disposed is defined as a downward direction in the semiconductor memory device 1.

As illustrated in FIGS. 1A and 1B, a memory region MR is disposed at a central portion of the plurality of word lines WL in the X direction, and staircase regions SR are disposed at both end portions of the plurality of word lines WL in the X direction. The memory region MR and the staircase regions SR are divided into a plurality of regions by a plurality of plate-like portions LI penetrating the plurality of word lines WL and the like and extending in the direction along the X direction.

Note that regions disposed between the plate-like portions LI adjacent in the Y direction and including the memory region MR and the staircase regions SR are referred to as block regions BLK. As will be described below, the memory region MR includes a plurality of memory cells that holds data in a nonvolatile manner, and the above-described block region BLK is an erase unit of the data.

In addition, between the plate-like portions LI adjacent in the Y direction, a plurality of separation layers SHEd penetrating the select gate lines SGD and extending in the direction along the X direction is disposed. The plurality of separation layers SHEd extends in the direction along the X direction over the entire memory region MR and reaches a part of the staircase regions SR at both end portions in the X direction.

Further, between the plate-like portions LI adjacent in the Y direction, one separation layer SHEs penetrating the select gate lines SGS and extending in the direction along the X direction is disposed. In FIG. 1B, the one separation layer SHEs indicated by the broken line extends in the direction along the X direction over the entire memory region MR and the entire staircase regions SR at both end portions in the X direction, and divides the select gate lines SGS in the Y direction.

The separation layer SHEs is preferably disposed at a position overlapping one of the aforementioned plurality of separation layers SHEd in an up-down direction. However, in FIG. 1B, the separation layers SHEs are illustrated at positions not vertically overlapping the separation layers SHEd in consideration of visibility of the drawing.

In the memory region MR, a plurality of pillars PL penetrating the word lines WL and the select gate lines SGD and SGS in the stacking direction is disposed. The lower ends of the pillars PL reach the source line SL. A plurality of memory cells is formed at intersection portions of the pillars PL and the word lines WL. As a result, the semiconductor memory device 1 is configured as, for example, a three-dimensional nonvolatile memory in which memory cells are three-dimensionally disposed in the memory region MR.

In the staircase regions SR, the plurality of word lines WL and the select gate lines SGD and SGS are processed into a staircase shape and terminate. At this time, as the distance from the memory region MR increases in the X direction, the plurality of word lines WL and the select gate lines SGD and SGS constituting terrace portions shift from the upper layer side to the lower layer side, so that the height position of the terrace portion lowers toward the source line SL side.

Note that the separation layers SHEd described above extend from the memory region MR to a portion of the staircase regions SR where the select gate lines SGD are processed into a staircase shape. As a result, in one block region BLK, the select gate lines SGD are separated into a plurality of regions. In other words, the separation layers SHEd penetrate the layers above the plurality of word lines WL, so that these upper layer portions are partitioned into patterns of the plurality of select gate lines SGD.

Contacts CC respectively connected to the word lines WL and the select gate lines SGD and SGS are disposed at terrace portions of steps including the plurality of word lines WL and the select gate lines SGD and SGS. In the word lines WL, one contact CC is connected for each layer in one block region BLK. In the select gate lines SGD, one contact CC is connected for each section separated by the separation layers SHEd per layer. In the select gate lines SGS, one contact CC is connected for each sub-region in one block region BLK separated by the one separation layer SHEs per layer.

Here, in one block region BLK, the plurality of contacts CC is disposed on one of the staircase regions SR on both sides in the X direction. In addition, when viewed on one side in the X direction, for example, the plurality of contacts CC is disposed every two block regions BLK.

That is, in the example of FIG. 1B, in the uppermost block region BLK in the drawing, a plurality of contacts CC is disposed, for example, in the staircase region SR on the left side in the drawing out of the staircase regions SR at both end portions in the X direction. In addition, in the block regions BLK one below and two below the above-described block region BLK, a plurality of contacts CC is disposed in the staircase region SR on the right side in the drawing out of the staircase regions SR at both end portions in the X direction. Further, in the lowermost block region BLK in the drawing, a plurality of contacts CC is disposed in the staircase region SR again on the left side in the drawing.

Accordingly, the contacts CC of the staircase regions SR at both end portions in the X direction illustrated in FIG. 1A belong to different block regions BLK, and are not actually located in the same cross section.

The word lines WL and the like stacked in multiple layers are individually led out by these contacts CC. More specifically, a write voltage, a read voltage, and the like are applied from these contacts CC to the memory cells included in the memory region MR at the central portions of the plurality of word lines WL via the word lines WL at the same height positions as the memory cells.

The plurality of word lines WL, the select gate lines SGD and SGS, the pillars PL, and the contacts CC are covered with an insulating layer 50. The insulating layer 50 also extends around these configurations.

The semiconductor substrate SB above the insulating layer 50 is, for example, a silicon substrate or the like. The peripheral circuits CBA including transistors TR, wiring, and the like are disposed on the surface of the semiconductor substrate SB. Various voltages applied from the contacts CC to the memory cells are controlled by the peripheral circuits CBA electrically connected to the contacts CC. As a result, the peripheral circuits CBA control the electrical operation of the memory cells.

The peripheral circuits CBA are covered with an insulating layer 40, and the insulating layer 40 and the insulating layer 50 covering the plurality of word lines WL and the like are joined to form the semiconductor memory device 1 including the configurations of the plurality of word lines WL and the select gate lines SGD and SGS, the pillars PL, the contacts CC, and the like, and the peripheral circuits CBA.

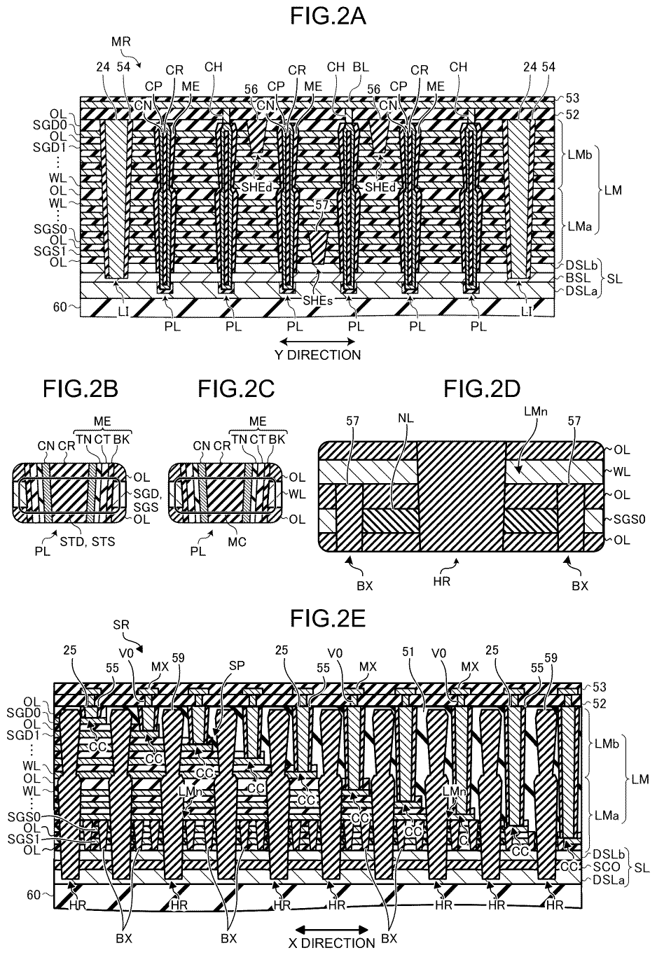

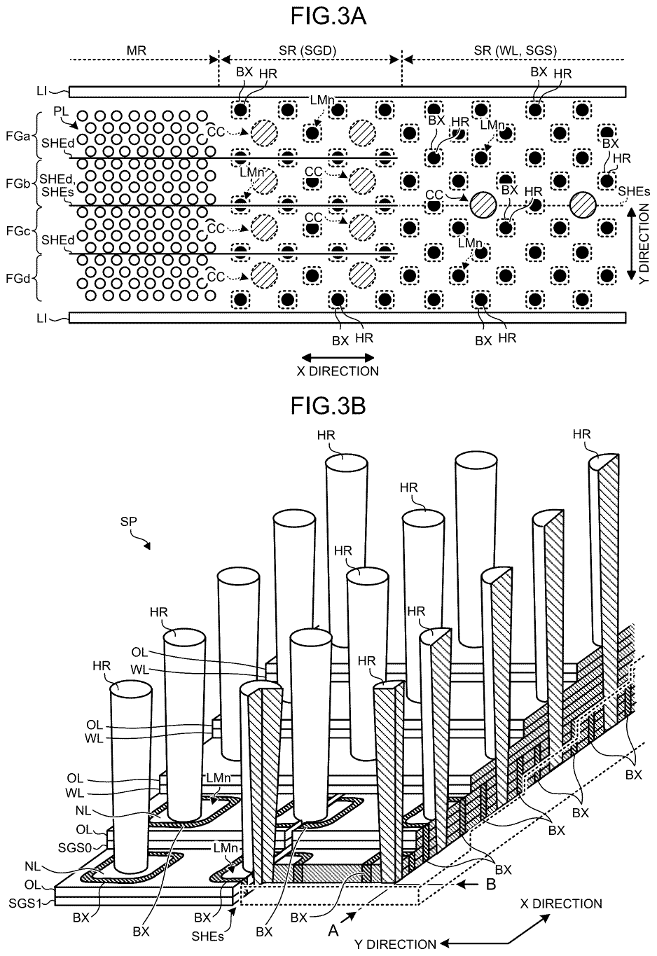

Next, a detailed configuration example of the semiconductor memory device 1 will be described with reference to FIGS. 2A to 3B. FIGS. 2A to 3B are views illustrating an example of a configuration of the semiconductor memory device 1 according to the embodiment.

More specifically, FIG. 2A is a cross-sectional view along the Y direction of the memory region MR of the semiconductor memory device 1. In FIG. 2A, structures below the insulating layer 60 and above an insulating layer 53 described below are omitted.

FIG. 2B is an enlarged cross-sectional view of the pillar PL at the height position of the select gate line SGD or SGS. FIG. 2C is an enlarged cross-sectional view of the pillar PL at the height position of the word line WL. FIG. 2D is an enlarged cross-sectional view of a columnar portion HR at the height positions of the word line WL and the select gate line SGS.

FIG. 2E is a cross-sectional view along the X direction in the staircase region SR of the semiconductor memory device 1. In FIG. 2E, structures below the insulating layer 60 and above the insulating layer 53 described below are omitted.

FIG. 3A is an XY cross-sectional view at the height position of the select gate line SGD illustrating a part of the memory region MR and the staircase region SR of the semiconductor memory device 1. FIG. 3B is a perspective cross-sectional view illustrating a part of staircase portions SP on the lower layer side including the select gate line SGS.

As illustrated in FIG. 2A, the source line SL has a multilayer structure in which, for example, a lower source line DSLa, an intermediate source line BSL, and an upper source line DSLb are stacked in this order on the insulating layer 60. Note that the intermediate source line BSL is disposed below the memory region MR of the stacked body LM.

The lower source line DSLa, the intermediate source line BSL, and the upper source line DSLb are, for example, polysilicon layers. Among them, at least the intermediate source line BSL may be a conductive polysilicon layer or the like in which impurities are diffused.

Note that the source line SL is connected to the peripheral circuits CBA via the electrode film EL by penetrating contacts, which are not illustrated, extending from the electrode film EL to the peripheral circuits CBA in the insulating layer 50 described above outside the stacked body LM.

The stacked body LM is disposed above the source line SL. The stacked body LM includes stacked bodies LMa and LMb in which a plurality of word lines WL and a plurality of insulating layers OL are alternately stacked one by one.

The stacked body LMa is disposed above the source line SL. A plurality of select gate lines SGS0 and SGS1 is disposed in this order from the upper layer side of the stacked body LMa via the insulating layers OL further below the lowermost word line WL of the stacked body LMa. The stacked body LMb is disposed above the stacked body LMa. A plurality of select gate lines SGD0 and SGD1 is disposed in this order from the upper layer side of the stacked body LMb via the insulating layers OL further above the uppermost word line WL of the stacked body LMb.

However, the number of word lines WL and select gate lines SGD and SGS stacked in the stacked body LM is arbitrary. The word lines WL and the select gate lines SGD and SGS are, for example, tungsten layers or molybdenum layers. The insulating layers OL are, for example, silicon oxide layers or the like.

The upper surface of the stacked body LM is covered with an insulating layer 52. The insulating layer 52 is covered with the insulating layer 53. Each of the insulating layers 52 and 53 constitutes a part of the insulating layer 50 in FIG. 1A together with an insulating layer 51 described below.

As described above, the stacked body LM is divided in the Y direction by the plurality of plate-like portions LI. That is, the plate-like portions LI are arranged in the Y direction and extend in the stacking direction of the stacked body LM and in a direction along the X direction.

As described above, the plate-like portions LI continuously extend in the stacked body LM from one end portion to the other end portion of the stacked body LM in the X direction. In addition, the plate-like portions LI penetrate the stacked body LM and the upper source line DSLb and reach the intermediate source line BSL in the memory region MR.

In addition, the plate-like portions LI have, for example, a tapered shape in which the width in the Y direction decreases from the upper end portion toward the lower end portion. Alternatively, the plate-like portions LI have, for example, a bowing shape in which the width in the Y direction is maximized at a predetermined position between the upper end portion and the lower end portion.

Each of the plate-like portions LI includes an insulating layer 54 and a conductive layer 24. The insulating layer 54 is, for example, a silicon oxide layer or the like. The conductive layer 24 is, for example, a tungsten layer or a conductive polysilicon layer. The insulating layer 54 covers the side walls of the plate-like portion LI facing each other in the Y direction. The inside of the insulating layer 54 is filled with the conductive layer 24.

However, instead of the plate-like portion LI described above, a plate-like member filled with the insulating layer may penetrate the stacked body LM and extend in the direction along the X direction, thereby dividing the stacked body LM in the Y direction.

Between the plate-like portions LI adjacent in the Y direction, the plurality of separation layers SHEd penetrating the upper layer portion of the stacked body LMb and extending in the direction along the X direction is disposed. These separation layers SHEd are insulating layers 56 such as silicon oxide layers that penetrate the select gate lines SGD0 and SGD1 and reach the insulating layer OL immediately below the select gate line SGD1.

In other words, these separation layers SHEd penetrating the upper layer portion of the stacked body LMb extend between the plate-like portions LI in the X direction over the memory region MR and a part of the staircase regions SR, so that the upper layer portion of the stacked body LMb is partitioned into the select gate lines SGD0 and SGD1 described above.

In addition, between the plate-like portions LI adjacent in the Y direction, one separation layer SHEs penetrating the select gate lines SGS0 and SGS1 that are lower layer portion of the stacked body LMa and extending in the direction along the X direction is disposed. The separation layer SHEs is an insulating layer 57 such as a silicon oxide layer that penetrates the insulating layer OL immediately above the select gate line SGS0, the select gate lines SGS0 and SGS1, the insulating layer OL between the select gate lines SGS0 and SGS1, and the insulating layer OL immediately below the select gate line SGS1, and reaches the upper source line DSLb.

The separation layer SHEs is preferably disposed near the center in the Y direction between the adjacent plate-like portions LI. In addition, also in FIG. 2A, the separation layer SHEs is drawn at a position not overlapping the above separation layers SHEd in the stacking direction due to drawing constraints, but as described above, the separation layer SHEs is preferably disposed at a position overlapping one of the plurality of separation layers SHEd in the stacking direction.

In the memory region MR, the plurality of pillars PL penetrating the stacked body LM, the upper source line DSLb, and the intermediate source line BSL and reaching the lower source line DSLa is dispersedly disposed.

The plurality of pillars PL is disposed, for example, in a staggered manner when viewed in the stacking direction of the stacked body LM. Each pillar PL has, for example, a circular shape, an elliptical shape, an oval shape, or the like as a cross-sectional shape in a direction along the layer of the stacked body LM, that is, in a direction along the XY plane.

In addition, each of the pillars PL has a tapered shape in which the diameter and the cross-sectional area decrease from the upper layer side toward the lower layer side in a portion penetrating the stacked body LMa and a portion penetrating the stacked body LMb. Alternatively, each of the pillars PL has, for example, a bowing shape in which the diameter and the cross-sectional area are maximized at a predetermined position between the upper layer side and the lower layer side in a portion penetrating the stacked body LMa and a portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering the upper surface of the channel layer CN, and a core layer CR serving as a core material of the pillar PL.

As illustrated in FIGS. 2B and 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except for the depth position of the intermediate source line BSL. In addition, the memory layer ME is also disposed on the bottom surface of the pillar PL reaching the depth of the lower source line DSLa.

The channel layer CN penetrates the stacked body LM, the upper source line DSLb, and the intermediate source line BSL inside the memory layer ME and reaches the depth of the lower source line DSLa. More specifically, the channel layer CN is disposed on the side surface and the bottom surface of the pillar PL while the outer periphery thereof is covered with the memory layer ME. However, a part of the channel layer CN is, on a side surface, in contact with the intermediate source line BSL, so that the channel layer CN is electrically connected to the source line SL including the intermediate source line BSL. The core layer CR is filled further inside the channel layer CN.

In addition, each of the plurality of pillars PL has the cap layer CP at the upper end portion. The cap layer CP is disposed at the upper end portion of the pillar PL so as to cover at least the upper end portion of the channel layer CN, and is connected to the channel layer CN. In addition, the cap layer CP is connected to a bit line BL disposed in the insulating layer 53 via a plug CH disposed in the insulating layer 52. The bit line BL extends above the stacked body LM in the direction along the Y direction so as to intersect with the lead-out direction of the word lines WL.

Note that, in FIG. 2A, the plugs CH are connected only to three pillars PL illustrated in FIG. 2A among the six pillars PL that penetrate the select gate lines SGD separated into three and are electrically connected to the bit line BL. The other pillars PL are connected to another bit line BL extending in the direction along the Y direction in parallel with the bit line BL illustrated in FIG. 2A via plugs CH, which are not illustrated in FIG. 2A, at positions different from the cross section illustrated in FIG. 2A.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 2C, with the above configuration, a memory cell MC is formed in each portion facing the individual word lines WL on the side surface of the pillar PL. When a predetermined voltage is applied from the word line WL, data is written to and read from the memory cell MC.

In addition, as illustrated in FIG. 2B, a select gate STD is formed in a portion where the side surface of the pillar PL faces the select gate lines SGD0 and SGD1 above the word lines WL. In addition, a select gate STS is formed in a portion where the side surface of the pillar PL faces the select gate lines SGS0 and SGS1 below the word lines WL.

When predetermined voltages are applied from the select gate lines SGD and SGS, the select gates STD and STS are turned on or off, and the memory cells MC of the pillar PL to which the select gates STD and STS belong can be brought into a selected state or a non-selected state.

As illustrated in FIG. 2E, the staircase region SR has staircase portions SP in which the plurality of word lines WL and the select gate lines SGD and SGS are processed into a staircase shape. The staircase portions SP illustrated in FIG. 2E are portions of the staircase region SR divided into the plurality of block regions BLK where the contacts CC are disposed and that have a function of leading out the word lines WL or the like.

The staircase portions SP are covered with the insulating layer 51. The insulating layer 51 reaches, for example, the height position of the uppermost layer of the stacked body LM, and the insulating layers 52 and 53 also cover the upper surface of the insulating layer 51. As described above, the insulating layer 51 also constitutes a part of the insulating layer 50 in FIG. 1A.

In addition, in the staircase region SR, the source line SL includes an intermediate insulating layer SCO interposed between the upper source line DSLb and the lower source line DSLa instead of the intermediate source line BSL. The intermediate insulating layer SCO is, for example, a silicon oxide layer or the like.

Therefore, in the staircase region SR, the plate-like portion LI penetrates the insulating layer 51, the stacked body LM, and the upper source line DSLb, and reaches the intermediate insulating layer SCO.

Each contact CC of the staircase portion SP penetrates the insulating layer 51 or the like and is connected to the word line WL or the select gate line SGD or SGS immediately below the insulating layer OL constituting each step of the staircase portion SP.

Each contact CC has, for example, a tapered shape in which the diameter and the cross-sectional area decrease from the upper end portion toward the lower end portion. Alternatively, the contact CC has, for example, a bowing shape in which the diameter and the cross-sectional area are maximized at a predetermined position between the upper end portion and the lower end portion.

In addition, the contact CC includes an insulating layer 55 covering the outer periphery of the contact CC, and a conductive layer 25 such as a tungsten layer or a copper layer filled inside the insulating layer 55.

The insulating layer 55 is a liner layer of the contact CC. The conductive layer 25 is a core layer serving as a core material of the contact CC, and is connected to upper layer wiring MX disposed in the insulating layer 53 via a plug V0 disposed in the insulating layer 52. The upper layer wiring MX is electrically connected to the peripheral circuits CBA (see FIG. 1A) described above.

With such a configuration, the respective word lines WL and the select gate lines SGD and SGS of the upper and lower layers of the word lines WL can be electrically led out from one end side or the other end side of the stacked body LM in the X direction. That is, with the above configuration, a predetermined voltage is applied from the peripheral circuit CBA to the memory cell MC via the upper layer wiring MX, the contact CC, the word line WL, and the like, and the memory cell MC can be operated as a storage element.

In addition, in the staircase region SR, the plurality of columnar portions HR penetrating the stacked body LM, the upper source line DSLb, and the intermediate insulating layer SCO and reaching the lower source line DSLa is dispersedly disposed. These columnar portions HR have, when forming the stacked body LM from the stacked body in which the sacrificial layer and the insulating layer are stacked, a role of supporting these configurations in the process of manufacturing the semiconductor memory device 1 to be described below, and do not contribute to the function of the semiconductor memory device 1.

Accordingly, each of the plurality of columnar portions HR is a single body of an insulating layer 59 such as a silicon oxide layer extending in the stacked body LM in the stacking direction, and is not electrically connected to the source line SL.

The plurality of columnar portions HR is disposed, for example, in a staggered manner or in a grid pattern when viewed in the stacking direction of the stacked body LM while avoiding interference with the plate-like portions LI and the contacts CC. Each columnar portion HR has, for example, a circular shape, an elliptical shape, an oval shape, or the like as a cross-sectional shape in a direction along the layer of the stacked body LM, that is, in a direction along the XY plane.

In addition, each of the columnar portions HR has a tapered shape in which the diameter and the cross-sectional area decrease from the upper layer side toward the lower layer side in a portion penetrating the stacked body LMa and a portion penetrating the stacked body LMb. Alternatively, each of the columnar portions HR has, for example, a bowing shape in which the diameter and the cross-sectional area are maximized at a predetermined position between the upper layer side and the lower layer side in a portion penetrating the stacked body LMa and a portion penetrating the stacked body LMb.

At the same height position of the stacked body LM, the cross-sectional area of the columnar portion HR in the direction along the XY plane is larger than, for example, the cross-sectional area of the pillar PL in the direction along the XY plane. In addition, the pitch between the plurality of columnar portions HR is larger than, for example, the pitch between the plurality of pillars PL, and the disposition density of the columnar portions HR per unit area of the word line WL in the stacked body LM is lower than the disposition density of the pillars PL per unit area of the word line WL.

As described above, for example, by configuring the cross-sectional area of the pillar PL to be smaller and having a narrower pitch than that of the columnar portion HR, a large number of memory cells MC can be formed at a high density in the stacked body LM having a predetermined size, and the storage capacity of the semiconductor memory device 1 can be increased. On the other hand, since the columnar portions HR are exclusively used to support the stacked body LM, it is possible to relax the processing accuracy at the time of forming the columnar portions HR by not having a precise configuration with a small cross-sectional area and a narrow pitch like the pillars PL, for example.

As illustrated in FIGS. 2D to 3B, in the stacked body LMa, block layers BX are disposed for respective columnar portions HR so as to surround the lower end portions of the columnar portions HR.

Note that, in FIG. 3A, the block layers BX are indicated by the broken lines, and the contacts CC connected to the select gate lines SGD are indicated by the broken lines. This is because, when FIG. 3A is an XY cross-sectional view at the height position of the lowermost select gate line SGD, the block layers BX disposed in the lower layer portion of the stacked body LM and the contacts CC located above the height position of the lowermost select gate line SGD do not appear in the cross section of FIG. 3A.

In addition, the perspective cross-sectional view of FIG. 3B illustrates a cross section in the X direction indicated by an arrow A and a cross section in the Y direction indicated by an arrow B. In addition, the staircase portion SP illustrated in FIG. 3B is a portion of the staircase region SR divided into the plurality of block regions BLK where the contacts CC are not disposed and that does not have a function of leading out the word lines WL or the like. However, also in the staircase portion SP having a function of leading out the word lines WL or the like, the columnar portions HR, the block layers BX, and the like have the same configurations as those in FIG. 3B.

Similarly to the separation layer SHEs described above, for example, the block layers BX are insulating layers 57 such as silicon oxide layers, and penetrate the lower end portion of the stacked body LMa from the insulating layer OL immediately above the select gate line SGS0 to reach the upper source line DSLb. That is, the height positions of the upper end portions of the separation layer SHEs and the block layers BX in the stacked body LMa are substantially equal.

More specifically, for example, as illustrated in FIG. 3B, in the staircase portion SP, in a region near the memory region MR including a portion in which the select gate line SGS0 on the upper layer side among the plurality of select gate lines SGS0 and SGS1 is processed into a staircase shape, the upper end portions of the separation layer SHEs and the block layers BX reach, for example, the upper surface of the insulating layer OL immediately above the select gate line SGS0. On the other hand, in a portion where the select gate line SGS1 on the lower layer side among the plurality of select gate lines SGS0 and SGS1 is processed into a staircase shape, the upper end portions of the separation layer SHEs and the block layers BX reach, for example, the upper surface of the insulating layer OL immediately above the select gate line SGS1 and do not extend upward therebeyond.

In regions surrounded by these block layers BX, insulating layers NL that are sacrificial layers before formation of the stacked body LM are disposed instead of the select gate line SGS. That is, a stacked structure LMn of the insulating layer NL and the insulating layer OL is disposed in the regions surrounded by the block layers BX. As a result, a plurality of stacked structures LMn is disposed in an island shape in the stacked body LM at positions corresponding to the plurality of columnar portions HR when viewed in the stacking direction of the stacked body LM. As described above, the plurality of stacked structures LMn locally surrounds the lower end portions of the plurality of columnar portions HR when viewed in the stacking direction of the stacked body LM.

The block layers BX surrounding the lower end portions of the columnar portions HR may have, for example, a substantially rectangular shape, as in the example of FIGS. 3A and 3B, when viewed in the stacking direction, and may have a circular shape, an elliptical shape, or other shapes. Even when the block layer BX has any shape, the area of the region surrounded by the block layer BX is preferably equal to or less than the cross-sectional area of the columnar portion HR of the portion where the columnar portion HR having a tapered shape or a bowing shape has the maximum diameter. That is, it is preferable that the region surrounded by the block layer BX be accommodated in an outer edge portion of the columnar portion HR at the portion where the columnar portion HR has the maximum diameter when viewed in the stacking direction.

In addition, the block layers BX may surround only the lower end portions of some columnar portions HR among the plurality of columnar portions HR, and the stacked structures LMn of the insulating layer NL and the insulating layer OL may be disposed. In addition, some columnar portions HR may be disposed so as to slightly protrude from the regions surrounded by the block layers BX due to positional deviation or the like at the time of forming the columnar portions HR. In addition, in a case where the columnar portion HR is disposed near an edge of a terrace part of the select gate line SGS processed into a staircase shape, or the like, the block layer BX may be disposed across a step portion between the select gate line SGS on the upper layer side and the select gate line SGS on the lower layer side.

Note that the stacked structures LMn of the insulating layer NL and the insulating layer OL disposed at the lower end portions of these columnar portions HR can also be regarded as second stacked bodies different from the stacked body LM. In such a second stacked body, even when the columnar portion HR is formed slightly protruding from the region surrounded by the block layer BX as described above, at least a part thereof overlaps the columnar portion HR when viewed in the stacking direction.

Hereinafter, the functions performed by the separation layers SHEd and SHEs in the electrical operation of the semiconductor memory device 1 will be described in more detail with continued reference to FIG. 3A.

Unlike the example illustrated in FIGS. 1B and 2A described above, in FIG. 3A, three separation layers SHEd extending to the region where the select gate lines SGD0 and SGD1 are processed into a staircase shape are disposed between the plate-like portions LI adjacent in the Y direction, and the select gate line SGD is separated into four sections in the Y direction. The contacts CC are disposed in each of these four sections.

That is, among these contacts CC, the four contacts CC arranged in the Y direction at positions near the memory region MR are connected to different sections of the select gate line SGD0, and the four contacts CC arranged in the Y direction at positions away from the memory region MR are connected to different sections of the select gate line SGD1.

In addition, the separation layer SHEs is disposed near the center in the Y direction of the plate-like portions LI adjacent in the Y direction so as to overlap one of the separation layers SHEd in the stacking direction. In FIG. 3A, the separation layer SHEs indicated by the broken line extends to a region where the plurality of word lines WL and the select gate lines SGS are processed into a staircase shape beyond a region where the select gate lines SGD are processed into a staircase shape.

In addition, at this time, the memory region MR sandwiched between the plate-like portion LI on the upper side of the drawing and the separation layers SHEd adjacent thereto is referred to as a region FGa. The memory region MR sandwiched between the separation layer SHEd adjacent to the plate-like portion LI on the upper side of the drawing and the separation layer SHEd at the center between the two plate-like portions LI is referred to as a region FGb. The memory region MR sandwiched between the separation layer SHEd at the center between the two plate-like portions LI and the separation layer SHEd adjacent to the plate-like portion LI on the lower side of the drawing is referred to as a region FGc. The memory region MR sandwiched between the separation layer SHEd adjacent to the plate-like portion LI on the lower side of the drawing and the plate-like portion LI on the lower side of the drawing is referred to as a region FGd.

In such a configuration, when data is read from a predetermined memory cell MC, in a case where the pillar PL to which the read target memory cell MC belongs is located in the region FGa, a predetermined voltage is applied to the select gate lines SGD0 and SGD1 corresponding to the region FGa, and the select gates STD of all the pillars PL located in the region FGa are turned on. In addition, a predetermined voltage is applied to the select gate lines SGS0 and SGS1 corresponding to the region on the upper side in the drawing with respect to the separation layer SHEs within the region between the two plate-like portions LI, and the select gates STS of all the pillars PL located in the regions FGa and FGb are turned on.

As a result, all the pillars PL in the region FGa in which both the select gates STD and STS are turned on are brought into a selected state, and the read target memory cell MC is specified by the word line WL and the bit line BL corresponding to the target memory cell MC, and data is read.

In addition, in a case where the pillar PL to which the read target memory cell MC belongs is located in the region FGb, a predetermined voltage is applied to the select gate lines SGD0 and SGD1 corresponding to the region FGb, and the select gates STD of all the pillars PL located in the region FGb are turned on. In addition, a predetermined voltage is applied to the select gate lines SGS0 and SGS1 corresponding to the region on the upper side in the drawing with respect to the separation layer SHEs within the region between the two plate-like portions LI, and the select gates STS of all the pillars PL located in the regions FGa and FGb are turned on.

As a result, all the pillars PL in the region FGb in which both the select gates STD and STS are turned on are brought into a selected state, and the read target memory cell MC is specified by the word line WL and the bit line BL corresponding to the target memory cell MC, and data is read.

In addition, in a case where the pillar PL to which the read target memory cell MC belongs is located in the region FGc, a predetermined voltage is applied to the select gate lines SGD0 and SGD1 corresponding to the region FGc, and the select gates STD of all the pillars PL located in the region FGc are turned on. In addition, a predetermined voltage is applied to the select gate lines SGS0 and SGS1 corresponding to the region on the lower side in the drawing with respect to the separation layer SHEs within the region between the two plate-like portions LI, and the select gates STS of all the pillars PL located in the regions FGc and FGd are turned on.

As a result, all the pillars PL in the region FGc in which both the select gates STD and STS are turned on are brought into a selected state, and the read target memory cell MC is specified by the word line WL and the bit line BL corresponding to the target memory cell MC, and data is read.

In addition, in a case where the pillar PL to which the read target memory cell MC belongs is located in the region FGd, a predetermined voltage is applied to the select gate lines SGD0 and SGD1 corresponding to the region FGd, and the select gates STD of all the pillars PL located in the region FGd are turned on. In addition, a predetermined voltage is applied to the select gate lines SGS0 and SGS1 corresponding to the region on the lower side in the drawing with respect to the separation layer SHEs within the region between the two plate-like portions LI, and the select gates STS of all the pillars PL located in the regions FGc and FGd are turned on.

As a result, all the pillars PL in the region FGd in which both the select gates STD and STS are turned on are brought into a selected state, and the read target memory cell MC is specified by the word line WL and the bit line BL corresponding to the target memory cell MC, and data is read.

Here, a predetermined voltage is also applied from the corresponding word line WL to a non-read target memory cell MC of the pillar PL in the selected state. At this time, in the pillar PL in a non-selected state in which only the select gate STS is turned on, a potential difference is generated between the channel layer CN of the pillar PL and the word lines WL, which becomes a parasitic capacitance, and it takes time until charges for reading data from the memory cell MC are accumulated in the channel layer CN of the pillar PL in the selected state.

As described above, by separating the select gate lines SGS0 and SGS1 into two sub-regions by the separation layer SHEs in the region between the plate-like portions LI adjacent in the Y direction, the number of pillars PL in the non-selected state in which the select gates STS are turned on can be greatly reduced. In the example of FIG. 3A, the number of pillars PL in the non-selected state in which the select gates STS are turned on can be reduced to about ⅓ as compared with the case where the separation layer SHEs is not provided.

### Method for Manufacturing Semiconductor Memory Device

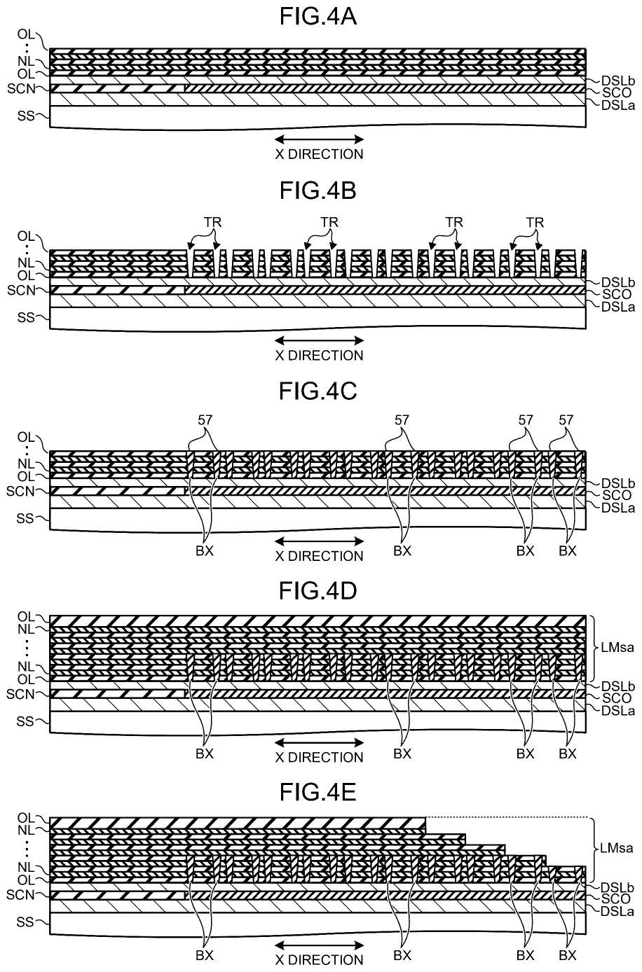

Next, a method for manufacturing the semiconductor memory device 1 of the embodiment will be described with reference to FIGS. 4A to 11C. FIGS. 4A to 11C are views sequentially illustrating a part of the procedure of the method for manufacturing the semiconductor memory device 1 according to the embodiment.

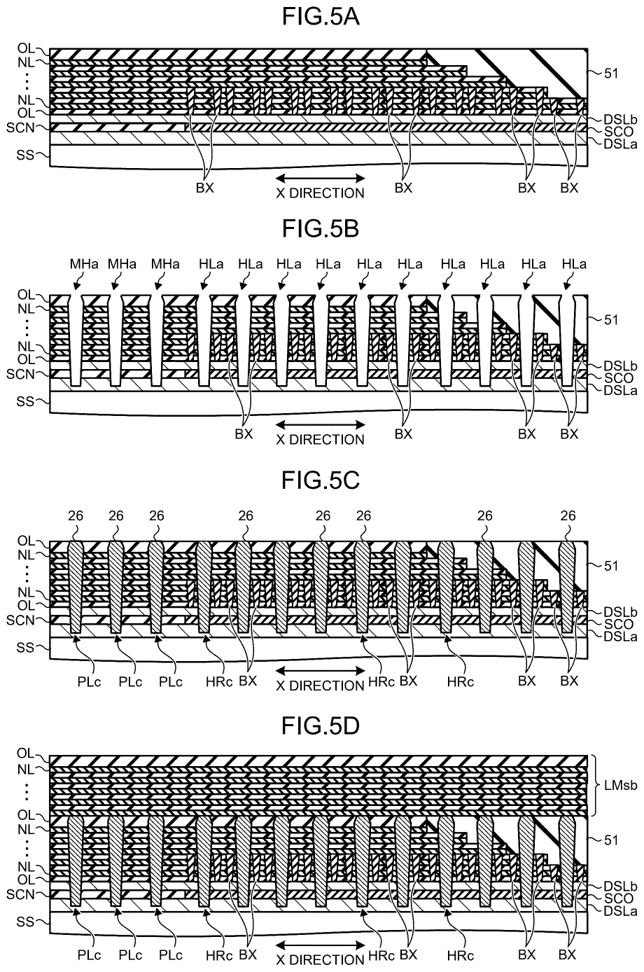

First, FIGS. 4A to 5D illustrate a stacked body LMsa, which is a lower layer portion of the stacked body LM before the word lines WL are formed, and a state where various configurations are formed in the stacked body LMsa.

FIGS. 4A to 5D are cross-sectional views along the X direction of a region that becomes the memory region MR and the staircase region SR later.

As illustrated in FIG. 4A, the lower source line DSLa, an intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (see FIG. 2A or the like) described above may be formed on the upper surface of the support substrate SS.

The intermediate sacrificial layer SCN is formed in a region on the support substrate SS that becomes the memory region MR later, and the intermediate insulating layer SCO is formed in a region on the support substrate SS that becomes the staircase region SR later. The intermediate sacrificial layer SCN is, for example, a silicon nitride layer or the like, and is a layer that is replaced with a polysilicon layer or the like later and becomes the intermediate source line BSL. As described above, the intermediate insulating layer SCO is, for example, a silicon oxide layer or the like.

In addition, a plurality of insulating layers NL and the plurality of insulating layers OL are alternately stacked one by one is formed on the upper source line DSLb. At this time, the insulating layers NL are stacked as many as the number of layers of the select gate lines SGS finally included in the semiconductor memory device 1. The insulating layers NL are, for example, silicon nitride layers or the like, and function as sacrificial layers that are later replaced with conductive materials and become the select gate lines SGS.

As illustrated in FIG. 4B, trenches TR having a frame shape that penetrate the plurality of insulating layers NL and OL and reach the upper source line DSLb are formed in a region that becomes the staircase region SR later.

As illustrated in FIG. 4C, the plurality of trenches TR is filled with the insulating layers 57. As a result, a plurality of block layers BX is formed. At this time, as described above, the area of the region surrounded by the block layer BX is preferably equal to or less than the cross-sectional area of the columnar portion HR in the portion where the columnar portion HR to be formed later has the maximum diameter.

Note that the process of FIGS. 4B and 4C is performed in association with the processing of forming the separation layer SHEs in the insulating layer NL that becomes the select gate line SGS later. That is, in parallel with the process of FIGS. 4B and 4C, trenches penetrating the plurality of insulating layers NL and OL and extending in the direction along the X direction in the insulating layers NL and OL are formed, and the trenches are filled with the insulating layers 57 to form the separation layer SHEs.

As illustrated in FIG. 4D, the stacked body LMsa in which a plurality of insulating layers NL and a plurality of insulating layers OL are further alternately stacked one by one on the plurality of insulating layers NL and OL is formed. The insulating layers NL additionally formed in the stacked body LMsa function as sacrificial layers that are later replaced with conductive layers and become the word lines WL.

As illustrated in FIG. 4E, the insulating layers NL and the insulating layers OL are processed into a staircase shape in a partial region of the stacked body LMsa, the region becoming the staircase region SR later. Such processing can be performed by repeating slimming of a mask pattern such as a photoresist layer and etching of the insulating layers NL and the insulating layers OL of the stacked body LMsa a plurality of times.

That is, a mask pattern is formed on the upper surface of the stacked body LMsa, and, for example, the insulating layer NL and the insulating layer OL in an exposed portion are etched away one by one. In addition, an end portion of the mask pattern is retracted by processing with oxygen plasma or the like to newly expose the upper surface of the stacked body LMsa, and the insulating layer NL and the insulating layer OL are further etched away one by one. By repeating such process a plurality of times, the staircase shape described above is formed.

At this time, the plurality of block layers BX is formed in the region of the stacked body LMsa that becomes the staircase region SR later. When the insulating layers NL on the lower layer side other than the uppermost insulating layer NL among the plurality of insulating layers NL that become the select gate lines SGS later are processed into a staircase shape, the upper end portions of the block layers BX formed in these portions are also processed to have substantially the same height as the upper surfaces of the insulating layers OL processed into a staircase shape.

As illustrated in FIG. 5A, the insulating layer 51 covering the stair part and reaching the height of the upper surface of the stacked body LMsa is formed. The insulating layer 51 is also formed in an outer region of the stacked body LMsa.

As illustrated in FIG. 5B, a plurality of memory holes MHa and a plurality of holes HLa extending through the stacked body LMsa in the stacking direction are formed.

The memory holes MHa are portions that later become lower structures of the pillars PL. The plurality of memory holes MHa is disposed in a region that later becomes the memory region MR, penetrates the stacked body LMsa, the upper source line DSLb, and the intermediate sacrificial layer SCN, and reaches the lower source line DSLa.

The holes HLa are portions that later become lower structures of the columnar portions HR. The plurality of holes HLa is disposed in a region that later becomes the staircase region SR, penetrates the insulating layer 51, the stacked body LMsa, the upper source line DSLb, and the intermediate sacrificial layer SCN, and reaches the lower source line DSLa. At this time, the lower end portion of each hole HLa is disposed within a region surrounded by the corresponding block layer BX among the plurality of block layers BX having a frame shape.

In addition, at this time, even when positional deviation occurs in some of the plurality of holes HLa so that the holes HLa are formed at a position slightly protruding from the regions surrounded by the corresponding block layers BX, there is no effect on the subsequent process.

As illustrated in FIG. 5C, the memory holes MHa and the holes HLa are filled with sacrificial layers 26 such as amorphous silicon layers or CVD-carbon layers. As a result, in a region that later becomes the memory region MR, pillars PLc in which the plurality of memory holes MHa is filled with the sacrificial layers 26 are formed. In addition, in a region that later becomes the staircase region SR, columnar portions HRc in which the plurality of holes HLa is filled with the sacrificial layers 26 is formed.

As illustrated in FIG. 5D, a stacked body LMsb that covers the stacked body LMsa including a portion processed into a staircase shape and in which the plurality of insulating layers NL and the plurality of insulating layers OL are alternately stacked one by one is formed. The stacked body LMsb is an upper layer portion of the stacked body LM before the word lines WL are formed. The insulating layers NL of the stacked body LMsb function as sacrificial layers that are later replaced with conductive layers and become the word lines WL or the select gate lines SGD.

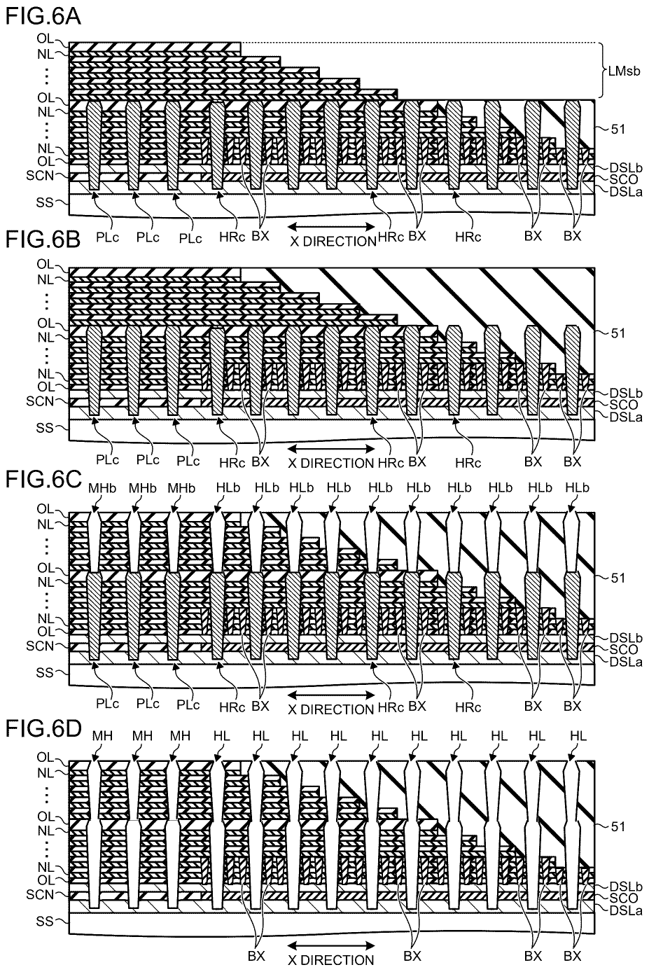

Next, FIGS. 6A to 6D illustrate a state in which various configurations are formed in the stacked bodies LMsa and LMsb. Similarly to FIGS. 4A to 5D, FIGS. 6A to 6D are cross-sectional views along the X direction of a region that becomes the memory region MR and the staircase region SR later.

As illustrated in FIG. 6A, the insulating layers NL and the insulating layers OL are processed into a staircase shape in a partial region of the stacked body LMsb. Similarly to the process illustrated in FIG. 4E described above, such processing can be performed by repeating slimming of a mask pattern such as a photoresist layer and etching of the insulating layers NL and the insulating layers OL of the stacked body LMsb a plurality of times.

At this time, the uppermost step of the stair part formed in the stacked body LMsa and the lowermost step of the stair part formed in the stacked body LMsb are brought close to each other so that they are formed continuously from the lower layer side of the stacked body LMsa to the upper layer side of the stacked body LMsb.

As illustrated in FIG. 6B, the insulating layer 51 covering the insulating layer 51 over the stacked body LMsa and the stair part newly formed in the stacked body LMsb and reaching the height of the upper surface of the stacked body LMsb is formed. The insulating layer 51 is also formed in an outer region of the stacked bodies LMsa and LMsb.

As illustrated in FIG. 6C, a plurality of memory holes MHb and a plurality of holes HLb extending through the stacked body LMsb in the stacking direction are formed.

The memory holes MHb are portions that later become upper structures of the pillars PL. The plurality of memory holes MHb is disposed in a region that later becomes the memory region MR, penetrates the stacked body LMsb, and respectively reaches the upper end portions of the pillars PLc formed in the stacked body LMsa.

The holes HLb are portions that later become upper structures of the columnar portions HR. The plurality of holes HLb is disposed in a region that later becomes the staircase region SR, penetrates the insulating layer 51 and the stacked body LMsb, and respectively reaches the upper end portions of the columnar portions HRc formed in the stacked body LMsa.

As illustrated in FIG. 6D, the sacrificial layers 26 are removed from the pillars PLc at the bottoms of the memory holes MHb. As a result, the memory holes MHa are opened respectively at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa is formed.

In parallel with this, the sacrificial layers 26 are removed from the columnar portions HRc at the bottom of the holes HLb. As a result, the holes HLa are opened respectively at the bottoms of the plurality of holes HLb, and a plurality of holes HL penetrating the insulating layer 51, the stacked bodies LMsb and LMsa, the upper source line DSLb, and the intermediate insulating layer SCO and reaching the lower source line DSLa is formed.

Note that, in a case where the sacrificial layers 26 filled in the pillars PLc and the columnar portions HRc are CVD-carbon layers or the like, the sacrificial layers 26 can be collectively removed from these pillars PLc and the columnar portions HRc when the mask pattern or the like used in the process of FIG. 6C described above is removed by ashing or the like using oxygen plasma.

Thereafter, although not illustrated, the insulating layer 59 is filled into the plurality of holes HL. At this time, the plurality of memory holes MH is protected by a photoresist layer or the like. As a result, the plurality of columnar portions HR is formed in the region that later becomes the staircase region SR.

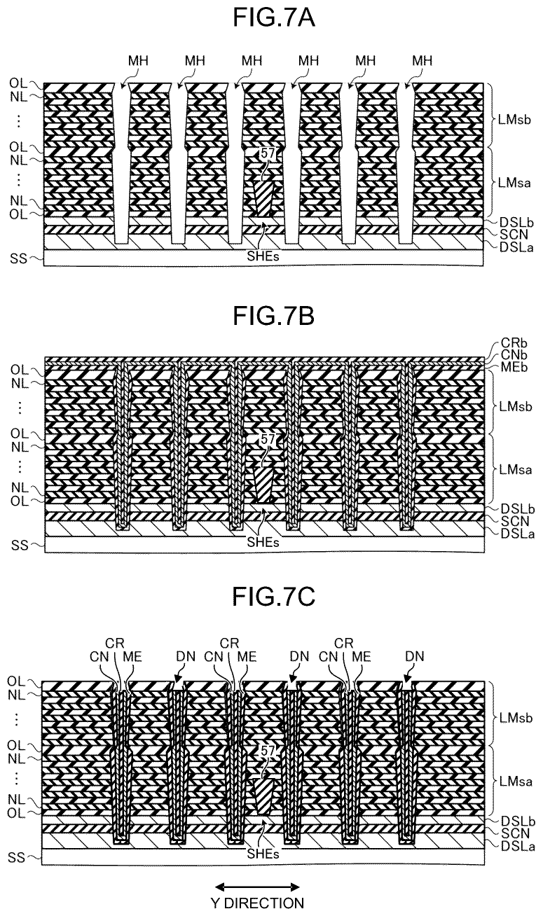

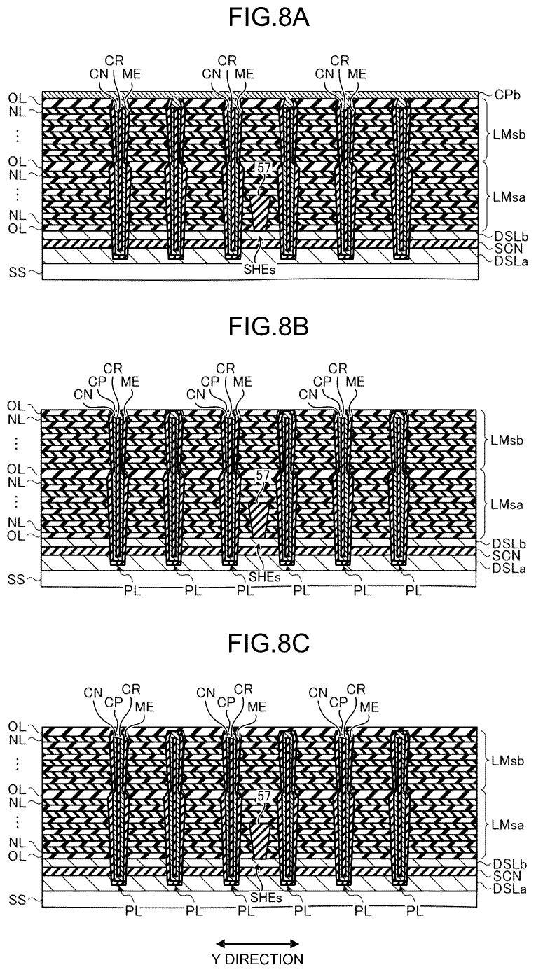

Next, a state where the pillars PL are formed by forming multilayer structures in the memory holes MH will be described with reference to FIGS. 7A to 8C. FIGS. 7A to 8C are cross-sectional views along the Y direction of a region that becomes the memory region MR later.

As illustrated in FIG. 7A, the plurality of memory holes MH is formed in a region that later becomes the memory region MR. In addition, in the lower layer portion of the stacked body LMsa, the separation layer SHEs formed in parallel with the block layers BX in the process of FIGS. 4B and 4C is disposed.

As illustrated in FIG. 7B, a multilayer insulating layer MEb, a semiconductor layer CNb, and an insulating layer CRb are formed in this order in the memory holes MH. As a result, the multilayer insulating layer MEb and the semiconductor layer CNb are disposed on the side surfaces of the memory holes MH and the bottom surfaces where the lower source line DSLa is exposed, and the insulating layer CRb is filled in central portions of the memory holes MH.

The multilayer insulating layer MEb is an insulating layer having a multilayer structure that becomes the memory layer ME later. The semiconductor layer CNb is a layer that becomes the channel layer CN later. The insulating layer CRb is a silicon oxide layer or the like that becomes the core layer CR later.

The multilayer insulating layer MEb, the semiconductor layer CNb, and the insulating layer CRb are also formed in this order on the upper surface of the stacked body LMsb.

As illustrated in FIG. 7C, in a region that later becomes the memory region MR, the insulating layer CRb, the semiconductor layer CNb, and the multilayer insulating layer MEb are sequentially etched back to be removed from the upper surface of the stacked body LMsb, and recesses DN from which the insulating layer CRb and the semiconductor layer CNb are removed are formed at the upper end portions of the memory holes MH.

As a result, the memory layers ME, the channel layers CN, and the core layers CR are formed in the memory holes MH in this order from the outer peripheral side.

As illustrated in FIG. 8A, in a region that later becomes the memory region MR, a semiconductor layer CPb is formed in the recesses DN at the upper end portions of the memory holes MH. The semiconductor layer CPb is a layer that becomes the cap layers CP later. The semiconductor layer CPb is also formed on the upper surface of the stacked body LMsb.

As illustrated in FIG. 8B, in a region that later becomes the memory region MR, the semiconductor layer CPb on the upper surface of the stacked body LMsb is removed by CMP or the like, and the cap layers CP are formed at the upper end portions of the memory holes MH.

As illustrated in FIG. 8C, an uppermost insulating layer OL of the stacked body LMsb thinned by CMP or the like is stacked back.

As a result, the pillars PL in which the cap layers CP are embedded in the uppermost insulating layer OL are formed. However, at this time point, the memory layer ME covers the entire side wall of the pillar PL, and a part of the side surface of the channel layer CN is not in a state of being exposed from the memory layer ME.

Note that the staircase structure of the stacked bodies LMsa and LMsb is appropriately applied to the stacked body LMsa and the stacked body LMsb. However, the formation of the staircase structure in the stacked bodies LMsa and LMsb may be collectively performed at this stage.

In this case, after the pillars PL and the columnar portions HR penetrating the stacked bodies LMsa and LMsb before the staircase structure is formed are formed, the staircase structure is collectively formed in a partial region of the stacked bodies LMsa and LMsb. At this time, the columnar portions HR are processed in parallel with the processing of the insulating layers NL and OL into a staircase shape, and the upper end portions of the individual columnar portions HR have substantially the same height as the upper surfaces of the insulating layers OL processed into a staircase shape.

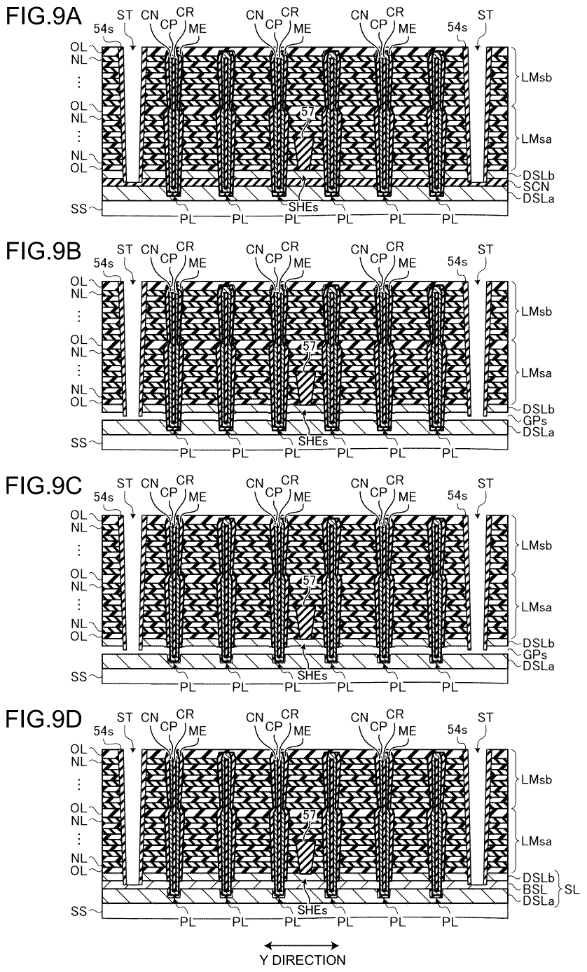

Next, a state where the source line SL and the word line WL are formed will be described with reference to FIGS. 9A to 11C. Similarly to FIGS. 7A to 8C, FIGS. 9A to 10C are cross-sectional views along the Y direction of a region that becomes the memory region MR later.

As illustrated in FIG. 9A, slits ST that penetrate the stacked bodies LMsb and LMsa and the upper source line DSLb and reach the intermediate sacrificial layer SCN are formed. In addition, insulating layers 54s are formed on the side walls of the slits ST facing each other in the Y direction.

The slit ST has a Y-direction longitudinal cross section of a tapered shape or a bowing shape, and also extends in the stacked bodies LMsa and LMsb in the direction along the X direction. Accordingly, in the staircase region SR, which is not illustrated, the lower end portion of the slit ST reaches the intermediate insulating layer SCO.

As illustrated in FIG. 9B, a removal liquid for the intermediate sacrificial layer SCN such as hot phosphoric acid is caused to flow through the slits ST whose side walls are protected by the insulating layers 54s, and the intermediate sacrificial layer SCN sandwiched between the lower source line DSLa and the upper source line DSLb is removed.

As a result, a gap layer GPs is formed between the lower source line DSLa and the upper source line DSLb. In addition, a part of the memory layers ME in the outer peripheral portions of the pillars PL is exposed in the gap layer GPs.

As illustrated in FIG. 9C, a chemical liquid is caused to appropriately flow into the gap layer GPs through the slits ST, and the block insulating layer BK, the charge storage layer CT, and the tunnel insulating layer TN (see FIGS. 2B and 2C) of the memory layer ME exposed in the gap layer GPs are sequentially removed. As a result, the memory layers ME are removed from partial side walls of the pillars PL, and a part of the channel layers CN on the inner side is exposed in the gap layer GPs.

As illustrated in FIG. 9D, a source gas such as amorphous silicon is injected from the slits ST whose side walls are protected by the insulating layers 54s, and the gap layer GPs is filled with amorphous silicon or the like. In addition, the support substrate SS is heat-treated to polycrystallize the amorphous silicon filled in the gap layer GPs, thereby forming the intermediate source line BSL containing polysilicon or the like.

As a result, a part of the channel layers CN of the pillars PL is connected to the source line SL on the side surfaces via the intermediate source line BSL.

At this time, in the staircase region SR, which is not illustrated, the gap layer GPs is not formed between the lower source line DSLa and the upper source line DSLb. In addition, the intermediate source line BSL is not formed.

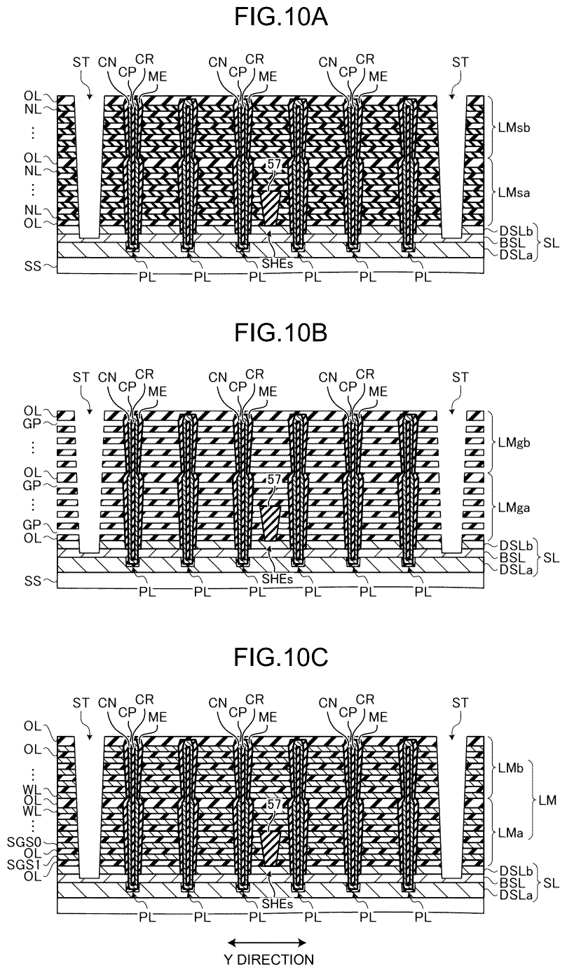

As illustrated in FIG. 10A, the insulating layers 54s on the side walls of the slits ST are temporarily removed.

As illustrated in FIG. 10B, a removal liquid for the insulating layers NL such as, for example, hot phosphoric acid is caused to flow into the stacked bodies LMsa and LMsb from the slits ST to remove the insulating layers NL of the stacked bodies LMsa and LMsb. As a result, stacked bodies LMga and LMgb including a plurality of gap layers GP from which the insulating layers NL between the insulating layers OL are removed are formed.

At this time, the insulating layers NL on the lower layer side where the separation layer SHEs is disposed are removed on each one side in the Y direction by the removal liquid flowing from the slits ST on both sides in the Y direction with the separation layer SHEs interposed therebetween. As described above, even when the separation layer SHEs is disposed, the entire insulating layers NL on the lower layer side can be removed.

The stacked bodies LMga and LMgb including the plurality of gap layers GP have a fragile structure. In a region that later becomes the memory region MR, the plurality of pillars PL supports such fragile stacked bodies LMga and LMgb.

Such a support structure of the pillars PL suppresses bending of the remaining insulating layers OL and distortion or collapse of the stacked bodies LMga and LMgb.

As illustrated in FIG. 10C, a source gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like. As a result, the stacked body LM including stacked bodies LMa and LMb in which the plurality of word lines WL and the like and the plurality of insulating layers OL are alternately stacked one by one is formed.

Also at this time, the gap layers GP on the lower layer side where the separation layer SHEs is disposed are filled, on each one side in the Y direction, with the conductive material that is the source gas flowing from the slits ST on both sides in the Y direction with the separation layer SHEs interposed therebetween. As described above, even when the separation layer SHEs is disposed, the entire gap layers GP on the lower layer side can be filled with the conductive material to form the select gate lines SGS.

Note that the uppermost conductive layer and the second conductive layer from the uppermost conductive layer of the stacked body LMb are partitioned into a pattern of the plurality of select gate lines SGD by forming the separation layers SHEd penetrating therethrough later.

As described above, the processing of forming the intermediate source line BSL from the intermediate sacrificial layer SCN and the processing of forming the word lines WL from the insulating layers NL are also referred to as replacement process.

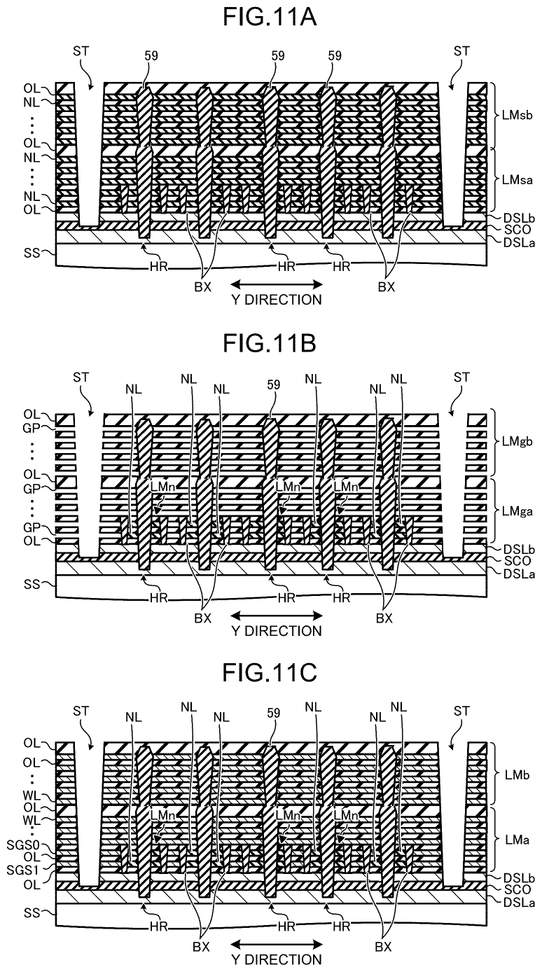

FIGS. 11A to 11C are cross-sectional views along the Y direction of a region that becomes the staircase region SR later, and illustrate processing performed in the region that becomes the staircase region SR in parallel with the process in FIGS. 10A to 10C described above. Note that FIGS. 11A to 11C illustrate a cross section of the uppermost step of the staircase portion SP.

As illustrated in FIG. 11A, in the region that later becomes the staircase region SR, the plurality of columnar portions HR has been formed. In addition, the slits ST described above are also formed in the region that becomes the staircase region SR later. However, in the region that later becomes the staircase region SR, the lower end portions of the slits ST reach the intermediate insulating layer SCO. Therefore, the region that later becomes the staircase region SR is not affected by the replacement process of the source line SL illustrated in FIGS. 9A to 9D described above.

As illustrated in FIG. 11B, in parallel with the above-described process of FIG. 10B, also in the region that later becomes the staircase region SR, the plurality of insulating layers NL of the stacked bodies LMsa and LMsb is removed, and the stacked bodies LMga and LMgb including the plurality of gap layers GP are formed.

At this time, in the region that later becomes the staircase region SR, the plurality of columnar portions HR supports the fragile stacked bodies LMga and LMgb. Such a support structure of the columnar portions HR suppresses bending of the remaining insulating layers OL and distortion or collapse of the stacked bodies LMga and LMgb.

However, as described above, the columnar portions HR have, for example, a tapered shape or a bowing shape, and the lower end portions of the columnar portions HR are thinner than, for example, the upper end portions of the columnar portions HR. Additionally, the columnar portions HR are disposed at a low density at intervals wider than intervals between the pillars PL. Accordingly, the function of the columnar portions HR for supporting the stacked bodies LMga and LMgb may be inferior to the function of the pillars PL for supporting the stacked bodies LMga and LMgb, and there is a possibility that the stacked bodies LMga and LMgb are not sufficiently supported in the region that becomes the staircase region SR later.

However, the plurality of block layers BX is formed at the lower end portions of the individual columnar portions HR so as to surround the lower end portions. Therefore, the removal liquid for the insulating layers NL such as hot phosphoric acid flowing from the slits ST does not flow into the regions surrounded by the block layers BX, and the insulating layers NL in this region are not removed.

At this time, as described above, some columnar portions HR may be formed at positions slightly protruding from the regions surrounded by the corresponding block layers BX due to, for example, positional deviation at the time of forming the holes HLa. Even when the columnar portion HR is formed so as to penetrate a part of the frame of the block layer BX due to positional deviation or the like, the region in the block layer BX is shielded from the outer region by the columnar portion HR itself and the remaining block layer BX, and the insulating layers NL in the region can be left.

As described above, the stacked structures LMn in which the insulating layers NL remain in the block layers BX are disposed in an island shape in the stacked body LMga, whereby the remaining insulating layers OL are further suppressed from being bent, and the stacked body LMga and the entire stacked bodies LMga and LMgb are further suppressed from being distorted or collapsed.

As described above, in the region that later becomes the staircase region SR, the stacked bodies LMga and LMgb are sufficiently supported by leaving the insulating layers NL in the block layers BX in addition to the support function of the columnar portions HR.

As illustrated in FIG. 11C, in parallel with the process of FIG. 10C described above, also in the region that later becomes the staircase region SR, the plurality of gap layers GP of the stacked bodies LMga and LMgb is filled with the conductive material, and the stacked body LM including the stacked bodies LMa and LMb in which the plurality of word lines WL and the like and the plurality of insulating layers OL are alternately stacked one by one is formed. In addition, the stacked structures LMn of the insulating layers NL that remain without being subjected to the replacement process are disposed in the block layers BX.

Note that, as described above, the block layers BX are configured such that the area of the region surrounded by the block layer BX is equal to or less than the cross-sectional area of the columnar portion HR, for example, in the portion where the columnar portion HR has the maximum diameter. As a result, the plane area of the insulating layers NL in the stacked structure LM can be set to an area sufficient to compensate for the thinning of the lower end portion of the columnar portion HR, the stacked bodies LMga and LMgb can be sufficiently supported, and the area can be supported such that the electrical resistance of the select gate lines SGS in the stacked body LM does not excessively increase.

Thereafter, the insulating layers 54 are formed on the side walls of the slits ST, and the insulating layers 54 are filled with the conductive layers 24 to form the plate-like portions LI. However, the insulating layers 54 or the like may be filled in the slits ST without forming the conductive layers 24 to form the plate-like members.

In addition, trenches penetrating the uppermost conductive layer and the second conductive layer from the uppermost conductive layer of the stacked body LMb are formed, and the insulating layers 56 are filled in the trenches to form the separation layers SHEd that partition these conductive layers into the pattern of the select gate lines SGD.

In addition, after the plurality of contacts CC is formed in the staircase portion SP, the insulating layer 52 is formed on the upper surface of the stacked body LM and the upper surface of the insulating layer 51 covering the staircase region SR, and the plugs V0 connected to the contacts CC are formed through the insulating layer 52. In addition, the plugs CH connected to the pillars PL are formed through the insulating layer 52. Further, the insulating layer 53 is formed on the insulating layer 52, and the upper layer wiring MX, the bit line BL, and the like connected to the plugs V0 and CH are formed. In addition, an electrode pad or the like for having electrical conduction with the peripheral circuits CBA is formed on the upper surface of the insulating layer 53.

Note that, for example, the plugs V0 and CH, the upper layer wiring MX, the bit line BL, and the like may be collectively formed by using a dual damascene method or the like.

In addition, the peripheral circuits CBA are formed on the semiconductor substrate SB separate from the support substrate SS on which the stacked body LM is formed, and are covered with the insulating layer 40. In the insulating layer 40, contacts, vias, wiring, or the like that lead the peripheral circuits CBA to the surface of the insulating layer 40 are formed and connected to the electrode pad or the like formed on the upper surface of the insulating layer 40.

Subsequently, the support substrate SS and the semiconductor substrate SB are bonded to each other by the insulating layers 50 and 40, and the electrode pads in the insulating layers 50 and 40 are connected. Thereafter, the support substrate SS is removed to expose the source line SL, and the electrode film EL is connected via the insulating layer 60 in which the plugs PG are formed.

Thus, the semiconductor memory device 1 of the embodiment is manufactured.

### Overview

In the process for manufacturing a semiconductor memory device such as a three-dimensional nonvolatile memory, a stacked body in which a conductive layer and an insulating layer are stacked may be formed by replacing a sacrificial layer in the stacked body with the conductive layer. In this case, the fragile stacked body including a plurality of gap layers may be bent or distorted during the replacement process.

At this time, in a staircase region in which columnar portions are disposed at a density lower than that of pillars disposed in a memory region, bending, distortion, and the like of the stacked body are more likely to be remarkable. In addition, when the pillars and the columnar portions are collectively formed, since the processing conditions are adjusted in accordance with memory holes of the finer pillars, the thinning of lower end portions of the columnar portions becomes remarkable, and this point may also promote bending, distortion, and the like of the stacked body in the staircase region.

According to the semiconductor memory device 1 of the embodiment, the stacked structures LMn are included, which are disposed at a predetermined depth in the stacked body LM and in which the plurality of insulating layers NL is stacked apart from each other at height positions corresponding to the select gate lines SGS located within the predetermined depth, and the columnar portions HR extending in the stacked body LM and the stacked structures LMn in the stacking direction of the stacked body LM in the staircase region SR are included. As a result, bending and distortion of the stacked bodies LMga and LMgb during the replacement process can be suppressed.

According to the semiconductor memory device 1 of the embodiment, the stacked structures LMn are disposed in the stacked body LM in an island shape at positions corresponding to the plurality of columnar portions HR when viewed in the stacking direction of the stacked body LM. As described above, by keeping the stacked structures LMn in the stacked body LM in local regions, it is possible to suppress an increase in electrical resistance of the select gate lines SGS due to the disposition of the stacked structures LMn.

According to the semiconductor memory device 1 of the embodiment, the stacked structures LMn of the insulating layers NL are disposed at substantially the same height position as the select gate lines SGS on the lower layer side among the plurality of word lines WL and the select gate lines SGD and SGS in the stacked body LM. Since the columnar portions HR have a shape in which the lower end portions are thin, bending and distortion of the stacked bodies LMga and LMgb during the replacement process can be more effectively suppressed by disposing the stacked structures LMn of the insulating layers NL on the lower layer side of the stacked body LM.

According to the semiconductor memory device 1 of the embodiment, the plurality of stacked structures LMn is disposed at positions corresponding to any one columnar portion HR of the plurality of columnar portions HR. In this manner, by disposing the stacked structures LMn of the insulating layers NL at the lower end portions of the individual columnar portions HR, bending and distortion of the stacked bodies LMga and LMgb during the replacement process can be further suppressed.

According to the semiconductor memory device 1 of the embodiment, the block layers BX surround the peripheries of the stacked structures LMn of the insulating layers NL when viewed in the stacking direction of the stacked body LM. As described above, by disposing the block layers BX around the stacked structures LMn, the stacked structures LMn can be left in the stacked body LM when the stacked body LM is formed by the replacement process.

According to the semiconductor memory device 1 of the embodiment, among the plurality of insulating layers NL in the stacked structures LMn, the uppermost insulating layer NL is disposed at substantially the same height position as the uppermost select gate line SGS of the one or more select gate lines SGS through which the separation layer SHEs penetrates. This indicates that the block layers BX are formed in parallel with the separation layer SHEs. Since the block layers BX are formed in parallel with the separation layer SHEs, an additional process for forming the block layers BX is not required. Therefore, the manufacturing cost of the semiconductor memory device 1 can be reduced.

### First Modification

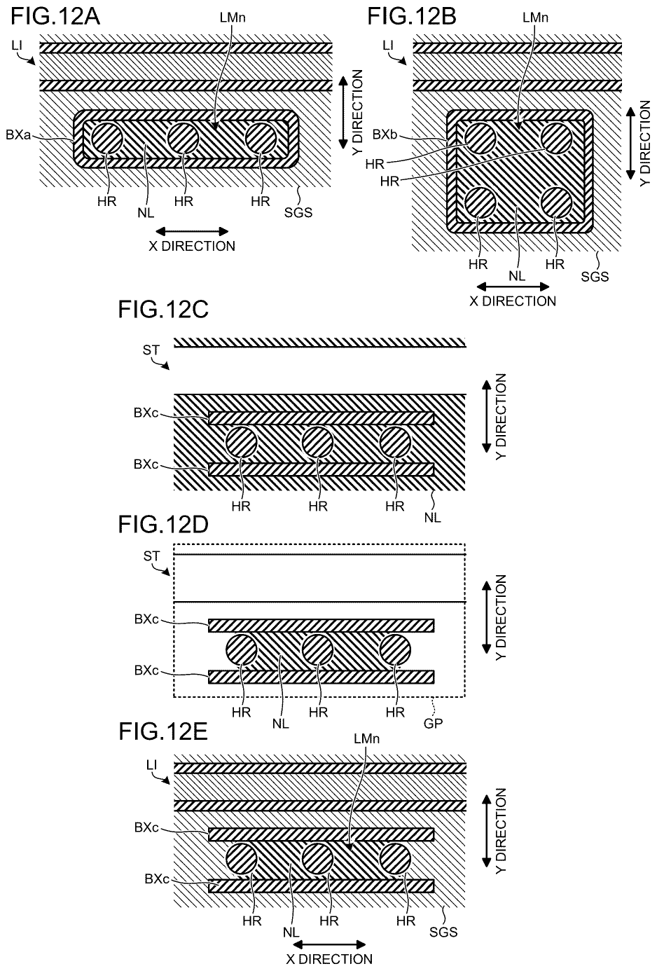

In the above-described embodiment, the block layers BX have, for example, a rectangular shape when viewed in the stacking direction of the stacked body LM and surround the individual columnar portions HR. However, the configuration of the block layer is not limited to the configuration of the above-described embodiment. FIGS. 12A to 12E illustrate some examples of a block layer having a configuration different from that of the above-described embodiment.

FIGS. 12A to 12E are XY cross-sectional views at a height position of a select gate line SGS illustrating some examples of a configuration of block layers BXa to BXc included in a semiconductor memory device according to a first modification of the embodiment. Note that, in FIGS. 12A to 12E, the same reference numerals are given to the same configurations as those of the above-described embodiment, and the description thereof may be omitted.

In the example illustrated in FIG. 12A, the block layer BXa has, for example, a rectangular shape with the X direction as a longitudinal direction when viewed in the stacking direction of the stacked body LM, and surrounds the plurality of columnar portions HR arranged in the X direction. As described above, one block layer BXa may be provided so as to surround the plurality of columnar portions HR instead of being provided corresponding to an individual columnar portion HR. Note that one block layer BXa may have a rectangular shape with the Y direction as a longitudinal direction when viewed in the stacking direction of the stacked body LM, and surrounds the plurality of columnar portions HR arranged in the Y direction.

In the example illustrated in FIG. 12B, for example, each side of the frame of the block layer BX has a length larger than the maximum diameter of one columnar portion HR, and the block layer BXb surrounds the plurality of columnar portions HR arranged in the X direction and the Y direction. As described above, when one block layer BXb surrounds the plurality of columnar portions HR, the plurality of columnar portions HR arranged in a plurality of rows in a predetermined direction may be collectively surrounded.

Note that, in the examples of FIGS. 12A and 12B described above, the number of columnar portions HR disposed in one block layer BXa or BXb is arbitrary. However, it is preferable to limit the number of columnar portions HR disposed in one block layer BXa or BXb so that the electrical resistance of the select gate lines SGS does not become too high due to an increase in plane area of the stacked structure LMn in the block layer BXa or BXb.

In the example illustrated in FIGS. 12C to 12E, the block layers BXc are, for example, two plate-like structures that are apart from each other in the Y direction and extend in the direction along the X direction, and are disposed on both sides in the Y direction of the plurality of columnar portions HR arranged in the X direction. As described above, the block layers BXc may be disposed on at least both sides in the Y direction of the target columnar portions HR, and may not completely surround these columnar portions HR.

When the removal liquid for the insulating layers NL is caused to flow through the slits ST as illustrated in FIG. 12D from the state before the replacement process in which the insulating layers NL are disposed on the entire XY cross section as illustrated in FIG. 12C, the removal liquid is temporarily blocked by the block layers BXc and does not flow into the region sandwiched on both sides in the Y direction by the block layers BXc. Thereafter, when the processing is ended before the removal liquid flows around from both sides in the X direction, the stacked structure LMn of the insulating layers NL can be left in the region sandwiched on both sides in the Y direction by the block layers BXc as illustrated in FIG. 12E.

As described above, also in the example of FIGS. 12C to 12E, it is possible to obtain the stacked structure LMn surrounding the lower end portions of the plurality of columnar portions HR arranged in the X direction by shielding the region having a length sufficient to block the inflow of the removal liquid with the block layers BXc while taking into consideration that the electrical resistance of the select gate lines SGS does not become too high.

According to the semiconductor memory device of the first modification, the plurality of columnar portions HR extends in the stacked structure LMn collectively surrounded by the block layer BXa or the block layer BXb. As a result, compared with the stacked structure LMn disposed to correspond to the individual columnar portions HR, the alignment accuracy at the time of forming the block layer BXa or BXb can be relaxed.

In addition, according to the semiconductor memory device of the first modification, the block layers BXc are disposed on both sides in the Y direction of the stacked structure LMn. As a result, the alignment accuracy at the time of forming the block layers BXc can be further relaxed.

According to the semiconductor memory device of the first modification, the same effects as those of the semiconductor memory device 1 of the embodiment described above are obtained.

### Second Modification

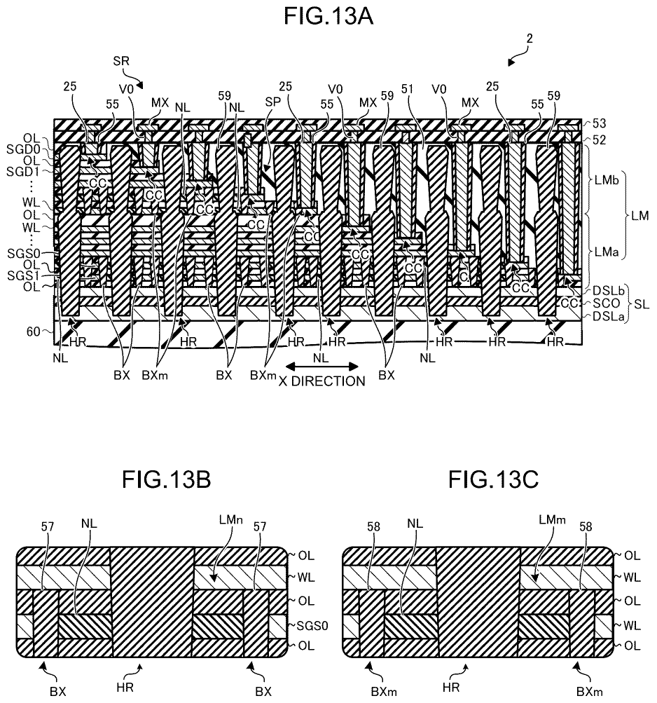

Next, a semiconductor memory device 2 of a second modification of the embodiment will be described with reference to FIGS. 13A to 13C. The semiconductor memory device 2 of the second modification is different from the above-described embodiment in that block layers BXm are also formed in the stacked body LMb.

FIGS. 13A to 13C are cross-sectional views illustrating an example of a configuration of the semiconductor memory device 2 according to the second modification of the embodiment.

More specifically, FIG. 13A is a cross-sectional view along the X direction in the staircase region SR of the semiconductor memory device 2. In FIG. 13A, structures below the insulating layer 60 and above the insulating layer 53 are omitted.

FIG. 13B is an enlarged cross-sectional view of a columnar portion HR at the height positions of the word line WL and the select gate line SGS of the stacked body LMa. FIG. 13C is an enlarged cross-sectional view of a columnar portion HR at the height positions of the word lines WL on the lower layer side of the stacked body LMb.

Note that, in FIGS. 13A to 13C, the same reference numerals are given to the same configurations as those of the above-described embodiment, and the description thereof may be omitted.

As illustrated in FIGS. 13A to 13C, the semiconductor memory device 2 of the second modification includes the block layers BXm and a stacked structure LMm of the insulating layers NL on the lower layer side in the stacked body LMb.

The block layers BXm penetrate, for example, some word lines WL and insulating layers OL on the lower layer side of the stacked body LMb and reach the uppermost insulating layer OL of the stacked body LMa. The block layer BXm may have the same shape as the block layer BX disposed in the stacked body LMa, for example, a rectangular shape when viewed in the stacking direction of the stacked body LM.

The stacked structure LMm in which the plurality of insulating layers NL and OL is stacked one by one is disposed in a region surrounded by or sandwiched between the block layers BXm. The number of insulating layers NL included in the stacked structure LMm is arbitrary. However, the number of the insulating layers NL is preferably determined in consideration of the electrical resistance and the like of the entire word lines WL in which the insulating layers NL are disposed.

As a result, the plurality of stacked structures LMm is disposed in the stacked body LMb in an island shape at positions corresponding to the plurality of columnar portions HR when viewed in the stacking direction of the stacked body LM. As described above, the plurality of stacked structures LMm locally surrounds the lower end portions of respective portions of the plurality of columnar portions HR penetrating the stacked body LMb when viewed in the stacking direction of the stacked body LM.

In the semiconductor memory device 2 of the second modification, the plurality of columnar portions HR has a configuration in which the lower end portions of portions penetrating the stacked body LMb are surrounded by the stacked structure LMm and the lower end portions of portions penetrating the stacked body LMa are surrounded by the stacked structure LMn.

As described above, for example, the columnar portions HR have a tapered shape or a bowing shape in both of the portion penetrating the stacked body LMb and the portion penetrating the stacked body LMa, and may also be thinned at the lower end portions of portions penetrating the stacked body LMb. Accordingly, by disposing the block layers BXm and the stacked structure LMm also at the lower end portions of the portions penetrating the stacked body LMb, bending and distortion of the stacked body LM at the time of replacement are further suppressed.

As described in the above embodiment, the block layers BXm and the stacked structure LMm as described above are formed in the stacked body LMb, for example, similarly to the block layers BX and the stacked structure LMn in the stacked body LMa. However, at the time of forming the block layers BXm, the above-described separation layer SHEs and the like are not formed, and the block layers BXm are formed alone.

Accordingly, the block layers BXm do not necessarily need to be formed at a position including the height position of the lowermost word line WL of the stacked body LMb, and may be formed, for example, at a position not including the height position of the lowermost word line WL on the lower layer side of the stacked body LMb or at a height position between the upper layer side and the lower layer side of the stacked body LMb. However, as described above, the block layers BXm and the stacked structure LMm are preferably disposed in the vicinity of the lower end portions of the portions of the columnar portions HR penetrating the stacked body LMb where the columnar portions HR are thinned to have a reduced support function.

According to the semiconductor memory device 2 of the second modification, the stacked structures LMn are included, which are disposed at a predetermined height position in the stacked body LMa in the stacking direction of the stacked body LM including the height position of the lowermost select gate line SGS of the stacked body LMa, in which the plurality of insulating layers NL is stacked apart from each other at height positions corresponding to the select gate lines SGS, and locally surround the lower end portions of the portions of one or more columnar portions HR among the plurality of columnar portions HR penetrating the stacked body LMa when viewed in the stacking direction of the stacked body LM. As a result, bending and distortion of the stacked bodies LMga and LMgb during the replacement process can be suppressed.

In addition, according to the semiconductor memory device 2 of the second modification, the stacked structures LMm are further included, in which the plurality of insulating layers NL is stacked apart from each other at the height positions corresponding to the word lines WL on the lower layer side of the stacked body LMb in the stacked body LMb in the stacking direction of the stacked body LM including the height position of the word lines WL on the lower layer side of the stacked body LMb, and locally surround the vicinity of the lower end portions of the portions of one or more columnar portions HR among the plurality of columnar portions HR penetrating the stacked body LMb when viewed in the stacking direction of the stacked body LM. As a result, bending and distortion of the stacked bodies LMga and LMgb during the replacement process can be further suppressed.

According to the semiconductor memory device 2 of the second modification, the same effects as those of the semiconductor memory device 1 of the embodiment described above are obtained.

### Another Embodiment

Note that, in the above-described embodiment and first and second modifications, in the method of leading out the plurality of word lines WL and the like on one side, the contacts are disposed every two block regions BLK in the staircase region SR on one side in the X direction. However, in the one-side lead-out method for the word lines WL and the like, it is sufficient to adopt a layout in which the contacts are disposed on one side in the X direction in the same block region BLK, and the disposition order is not limited to the above.

In addition, in the above-described embodiment and first and second modifications, before forming the word lines WL or the like that are tungsten layers or molybdenum layers, a metal element-containing block layer such as an aluminum oxide layer and a barrier metal layer such as a titanium nitride layer or a molybdenum nitride layer may be provided in this order from the outer peripheral side on the upper and lower surfaces of the word lines WL or the like facing the insulating layers OL and the portions facing the side surfaces of the pillars PL.

In addition, in the above-described embodiment and first and second modifications, the stacked body LM having a two-tier structure is provided. However, the configuration of the stacked body may be a one-tier structure or a three-tier structure or more.

In addition, in the above-described embodiment and first and second modifications, the pillars PL are connected to the source line SL on the side surfaces of the channel layers CN, but it is not limited thereto. For example, the pillar may be configured to be connected to the source line at the lower end portion of the channel layer by removing the memory layer on the bottom surface of the pillar.

In addition, in the above-described embodiment and first and second modifications, the peripheral circuits CBA are disposed above the stacked body LM. However, the peripheral circuit may be disposed below the stacked body or in the same layer as the stacked body.

In a case where the peripheral circuit is disposed below the stacked body, for example, the source line and the stacked body can be formed on the insulating layer of the semiconductor substrate having the peripheral circuit covered with the insulating layer. In a case where the peripheral circuit is disposed in the same layer as the stacked body, the stacked body can be formed at a position different from the peripheral circuit on the semiconductor substrate on which the peripheral circuit is formed.

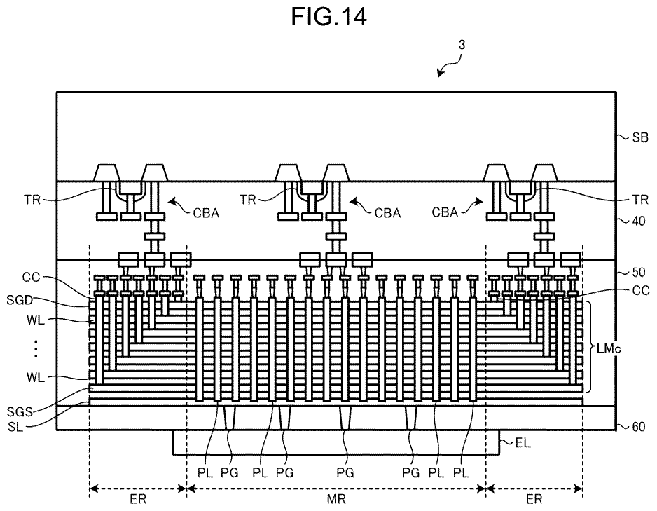

In addition, in the above-described embodiment and first and second modifications, the stacked body LM includes the staircase regions SR, but it is not limited thereto. FIG. 14 illustrates an example of a semiconductor memory device 3 without the staircase regions SR.

FIG. 14 is a cross-sectional view illustrating a schematic configuration example of the semiconductor memory device 3 according to another modification of the embodiment.

As illustrated in FIG. 14, the memory region MR is disposed at a central portion of a stacked body LMc included in the semiconductor memory device 3, and contact regions ER are disposed at both end portions of the stacked body LMc.

In the contact regions ER, a plurality of contacts CC penetrating the stacked body LMc to depth positions of predetermined word lines WL and the like and respectively connected to the plurality of word lines WL and the like is disposed. Also with such a configuration, the word lines WL and the like stacked in multiple layers can be individually led out.

In addition, in such a configuration, similarly to the above-described embodiment and the like, a plurality of columnar portions can be disposed in the contact regions ER, and the configuration of the above-described embodiment or first and second modifications can be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of conductive layers is stacked apart from each other;
a second stacked body that is disposed at a predetermined depth in the first stacked body in a stacking direction of the first stacked body, in which a plurality of first insulating layers is stacked apart from each other at height positions corresponding to conductive layers located within the predetermined depth among the plurality of conductive layers;
a plurality of pillars that is disposed in a first region and extends in the first stacked body in the stacking direction, in which a memory cell is formed at each of intersection portions with at least a part of the plurality of conductive layers; and
a plurality of columnar portions that is disposed in a second region different from the first region and extends in the first and second stacked bodies in the stacking direction, wherein
the second stacked body is disposed in an island shape in the first stacked body at a position corresponding to one or more columnar portions among the plurality of columnar portions when viewed in the stacking direction.

2. The semiconductor memory device according to claim 1, wherein
the second stacked body disposed in the island shape in the first stacked body is disposed at a height position corresponding to conductive layers on a lower layer side among the plurality of conductive layers, and
a lowermost first insulating layer of the plurality of first insulating layers is disposed at substantially a same height position as a lowermost conductive layer among the plurality of conductive layers in the first region.

3. The semiconductor memory device according to claim 1, wherein
the second stacked body disposed in the island shape in the first stacked body is disposed at a height position corresponding to conductive layers between a conductive layer on an upper layer side and a conductive layer on a lower layer side of the plurality of conductive layers.

4. The semiconductor memory device according to claim 1, wherein
a plurality of second stacked bodies including the second stacked body is disposed in the island shape when viewed in the stacking direction at the predetermined depth in the first stacked body, and
the plurality of second stacked bodies is disposed at positions corresponding to any one columnar portion of the plurality of columnar portions.

5. The semiconductor memory device according to claim 1, wherein
the second stacked body is disposed at a position corresponding to two or more columnar portions among the plurality of columnar portions.

6. The semiconductor memory device according to claim 1, further comprising:
first and second plate-like portions that extend in both the stacking direction and a first direction intersecting the stacking direction in the first stacked body while being spaced apart from each other by a predetermined distance, and divide the first stacked body in a second direction intersecting both the first direction and the stacking direction; and
a second insulating layer that is disposed on at least both sides of the second stacked body in the second direction.

7. The semiconductor memory device according to claim 6, wherein
the second insulating layer surrounds a periphery of the second stacked body when viewed in the stacking direction.

8. The semiconductor memory device according to claim 1, further comprising:
first and second plate-like portions that extend in both the stacking direction and a first direction intersecting the stacking direction in the first stacked body while being spaced apart from each other by a predetermined distance, and divide the first stacked body in a second direction intersecting both the first direction and the stacking direction; and
a separation layer that penetrates conductive layers continuously stacked in the stacking direction including a lowermost conductive layer of the first stacked body among the plurality of conductive layers and extends in the first direction in the first stacked body between the first and second plate-like portions, wherein
an uppermost first insulating layer of the second stacked body among the plurality of first insulating layers is disposed at substantially a same height position as an uppermost conductive layer of the conductive layers through which the separation layer penetrates.

9. A semiconductor memory device comprising:
a first stacked body in which a plurality of conductive layers is stacked apart from each other;
a plurality of pillars that is disposed in a first region and extends in the first stacked body in a stacking direction of the first stacked body, in which a memory cell is formed at each of intersection portions with at least a part of the plurality of conductive layers;
a plurality of columnar portions that is disposed in a second region different from the first region and extends in the first stacked body in the stacking direction;
a second stacked body that is disposed at a predetermined depth in the stacking direction in the first stacked body, in which a plurality of first insulating layers is stacked apart from each other at height positions corresponding to conductive layers located within the predetermined depth among the plurality of conductive layers, and at least a part of which overlaps one or more columnar portions among the plurality of columnar portions when viewed in the stacking direction; and
a second insulating layer that surrounds a periphery of the second stacked body when viewed in the stacking direction.

10. The semiconductor memory device according to claim 9, wherein
the second stacked body is disposed in the first stacked body at a height position corresponding to conductive layers on a lower layer side among the plurality of conductive layers, and
a lowermost first insulating layer of the plurality of first insulating layers is disposed at substantially a same height position as a lowermost conductive layer among the plurality of conductive layers in the first region.

11. The semiconductor memory device according to claim 9, further comprising:
first and second plate-like portions that extend in both the stacking direction and a first direction intersecting the stacking direction in the first stacked body while being spaced apart from each other by a predetermined distance, and divide the first stacked body in a second direction intersecting both the first direction and the stacking direction; and
a separation layer that penetrates conductive layers continuously stacked in the stacking direction including a lowermost conductive layer of the first stacked body among the plurality of conductive layers and extends in the first direction in the first stacked body between the first and second plate-like portions, wherein
an uppermost first insulating layer of the second stacked body among the plurality of first insulating layers is disposed at substantially a same height position as an uppermost conductive layer of the conductive layers through which the separation layer penetrates.

12. A semiconductor memory device comprising:
a first stacked body in which a plurality of first conductive layers is stacked apart from each other;
a plurality of first pillar portions that is disposed in a first region and extends in the first stacked body in a stacking direction of the first stacked body, in which a first memory cell is formed at each of intersection portions with at least a part of the plurality of first conductive layers;
a plurality of first columnar portions that is disposed in a second region different from the first region and extends in the first stacked body in the stacking direction; and
a second stacked body that is disposed at a predetermined height position in the first stacked body in the stacking direction including a height position of a lowermost first conductive layer of the plurality of first conductive layers in the first region, in which a plurality of first insulating layers is stacked apart from each other at height positions corresponding to any of the plurality of first conductive layers, and locally surrounds a lower end portion of at least one first columnar portion among the plurality of first columnar portions when viewed in the stacking direction.

13. The semiconductor memory device according to claim 12, wherein
a plurality of second stacked bodies including the second stacked body is disposed at the predetermined height position in the first stacked body, and
the plurality of second stacked bodies locally surrounds a lower end portion of at least any one columnar portion of the plurality of first columnar portions respectively.

14. The semiconductor memory device according to claim 12, wherein
the second stacked body locally surrounds lower end portions of two or more columnar portions of the plurality of first columnar portions.

15. The semiconductor memory device according to claim 12, further comprising:
first and second plate-like portions that extend in both the stacking direction and a first direction intersecting the stacking direction in the first stacked body while being spaced apart from each other by a predetermined distance, and divide the first stacked body in a second direction intersecting both the first direction and the stacking direction; and
a second insulating layer that is disposed on at least both sides of the second stacked body in the second direction.

16. The semiconductor memory device according to claim 15, wherein
the second insulating layer surrounds a periphery of the second stacked body when viewed in the stacking direction.

17. The semiconductor memory device according to claim 15, further comprising:
a separation layer that penetrates first conductive layers continuously stacked in the stacking direction including the lowermost first conductive layer of the first stacked body and extends in the first direction in the first stacked body between the first and second plate-like portions, wherein
the second insulating layer is disposed at substantially a same height position as the separation layer.

18. The semiconductor memory device according to claim 12, further comprising:
a third stacked body that is disposed above the first stacked body, in which a plurality of second conductive layers is stacked apart from each other;
a plurality of second pillar portions that is disposed in the first region, extends in the third stacked body in the stacking direction, and respectively connected, on lower end portions, to upper end portions of the plurality of first pillar portions, in which a second memory cell is formed at each of intersection portions with at least a part of the plurality of second conductive layers;
a plurality of second columnar portions that is disposed in the second region, extends in the third stacked body in the stacking direction, and respectively connected, on lower end portions, to upper end portions of the plurality of first columnar portions; and
a fourth stacked body that is disposed at a predetermined height position in the third stacked body in the stacking direction including a height position of a second conductive layer on a lower layer side among the plurality of second conductive layers in the first region, in which one or more third insulating layers are disposed at respective height positions corresponding to any of the plurality of second conductive layers, and locally surrounds a vicinity of a lower end portion of at least one second columnar portion among the plurality of second columnar portions when viewed in the stacking direction.

19. The semiconductor memory device according to claim 18, further comprising:
first and second plate-like portions that extend in both the stacking direction and a first direction intersecting the stacking direction in the first and third stacked bodies while being spaced apart from each other by a predetermined distance, and divide the first and third stacked bodies in a second direction intersecting both the first direction and the stacking direction; and
a fourth insulating layer that is disposed on at least both sides of the fourth stacked body in the second direction.

20. The semiconductor memory device according to claim 19, wherein
the fourth insulating layer surrounds a periphery of the fourth stacked body when viewed in the stacking direction.
